(19) United States
(12) Patent Application Publication
(10) Pub. No.: US 2025/0357065 A1
(43) Pub. Date: Nov. 20, 2025

(54) METHODS AND DEVICES FOR THE CONTACTLESS SETTING OF AN ELECTROSTATIC CHARGE OF A SAMPLE

(71) Applicant: Carl Zeiss SMT GmbH, Oberkochen (DE)

(72) Inventor: Daniel Rhinow, Frankfurt (DE)

(21) Appl. No.: 19/278,910

(22) Filed: Jul. 24, 2025

Related U.S. Application Data
(63) Continuation of application No. PCT/EP2024/051207, filed on Jan. 19, 2024.

(30) Foreign Application Priority Data
Jan. 25, 2023 (DE) 102023200591.3

(51) Int. Cl. H01J 37/02

(52) U.S. Cl. CPC H01J 37/026; H01J 2237/0044

(57) ABSTRACT

The present application relates to a method and to a device for setting an electrostatic charge of a sample. The method comprises the following steps: (a) adjusting at least one parameter of at least one particle beam such that, on average, each particle, incident on the sample, of the at least one particle beam releases a predefined average number of electrons from the sample; and (b) irradiating the sample with the at least one adjusted particle beam in order to set the electrostatic charge of the sample.

### CROSS-REFERENCE TO RELATED APPLICATIONS

This application is a continuation of and claims benefit under 35 U.S.C. § 120 from PCT Application No. PCT/EP2024/051207, filed on Jan. 19, 2024, which claims the priority of German patent application DE 10 2023 200 591.3 entitled “Verfahren und Vorrichtung zum kontaktlosen Einstellen einer elektrostatischen Aufladung einer Probe” [Method and device for the contactless setting of an electrostatic charge of a sample], which was filed at the German Patent and Trademark Office on Jan. 25, 2023. The entire contents of each of these earlier applications are incorporated herein by reference.

### TECHNICAL FIELD

The present invention relates to a method and to a device for the contact-free setting of an electrostatic charge of a sample, in particular a lithographic mask.

### BACKGROUND

As a consequence of the constantly increasing integration density in microelectronics, lithographic masks have to image structure elements that are becoming ever smaller into a photoresist layer of a wafer. In order to meet these requirements, the exposure wavelength is being shifted to ever shorter wavelengths. At the present time, argon fluoride (ArF) excimer lasers are principally used for exposure purposes, these lasers emitting at a wavelength of 193 nm. Intensive work is being done in regard to light sources which emit in the extreme ultraviolet (EUV) wavelength range (10 nm to 15 nm), and corresponding EUV masks. The resolution capability of wafer exposure processes has been increased by simultaneous development of multiple variants of conventional lithographic masks. Examples thereof are phase masks or phase-shifting masks and masks for multiple exposure.

On account of the ever decreasing dimensions of the structure elements, lithographic masks, in particular photolithographic masks, cannot always be produced without defects. Owing to the costly production of photomasks, defective photomasks, whenever possible, are repaired. Two important groups of defects of photolithographic masks are, firstly, dark defects. These are locations at which absorber or phase-shifting material is present, but which should be free of this material. These defects are repaired by removing the excess material preferably with the aid of a local etching process. Secondly, there are so-called clear defects. These are defects on the photomask which, upon optical exposure in a wafer stepper or wafer scanner, have a greater light transmissivity than an identical defect-free reference position. In mask repair processes, these defects may be eliminated by depositing a material having suitable optical properties. Ideally, the optical properties of the material used for the repair should correspond to those of the absorber or phase-shifting material.

Defects may furthermore be subdivided into printable and non-printable defects. During exposure of a wafer, photomasks having printable defects or printable mask defects generate a pattern that does not meet all design specifications. By contrast, during exposure of a wafer, a mask having one or more non-printable defects generates a pattern on the wafer that meets all of the design specifications. If defects are mentioned below, these are understood to mean only printable or printing defects.

US 2002/0070340 A1 describes an electron microscope that uses two beams containing low-energy electrons (LEEM, low-energy electron microscope). The low-energy beam releases less than one electron per electron of the primary beam incident on the sample from the sample and compensates for a yield of the higher-energy primary beam, which is >1, such that no electrostatic charging of the sample occurs.

The applicant develops and manufactures measuring apparatuses for analyzing photolithographic masks that are sold under the trade name PROVE®, AIMS™ or WLCD, for example. Furthermore, the applicant develops and sells repair devices for photolithographic masks that are known under the trade names MeRiT®, RegC® or ForTune®, for example.

The repair is typically effected with a particle beam (comprising for example electrons, ions, atoms, molecules and/or high-energy photons) with specific beam parameters. Together with a precursor gas to which the sample, for example the mask, is exposed, the particle beam excites a local chemical reaction on a sample, for instance a photomask, under defined process parameters. In this case, material may be deposited locally on the sample or material may be removed locally from the sample.

Examining and/or processing a sample using particle beams is often associated with the introduction of charges and/or the generation of charges, typically of electrons, in the sample. By way of example, electric charge may be accumulated by mechanical processes and/or during processing and/or imaging of a sample, such as a semiconductor substrate, by way of charged particles and/or EUV photons. This often results in electrical or electrostatic charging of the sample. The charging causes distortions in the imaging of a site to be analyzed, such as a defect, and thereby worsens the quality of the imaging of a defective site and/or of a process of processing the defect in the sample.

In conductive samples, locally generated electric charges are distributed within the sample, which is thereby electrostatically charged as a whole. Grounding the sample makes it possible to largely prevent electrostatic charging. The local generation of electric charges in a non-conductive sample leads to local electrostatic charging of the sample together with the associated electric field. As described in EP 158 7128, the effect of electrostatic charging on a beam of charged particles is able to be significantly reduced by a metal diaphragm mounted at a small distance above the sample. However, the diaphragm may adversely affect the imaging and/or processing of the sample, and it is not able to be used in some applications.

What is known as a flood gun or a plasma may be used to compensate for electrostatic charging. When used, however, the site to be analyzed or to be processed is usually irradiated directly over a large area. In the case of mask repair, there is the risk here of unwanted interaction with the particle beam-induced process. In addition, the large-area application of a plasma-charged particle may lead to a chemical change in sample constituents. Moreover, in both cases, it is not possible to set a specific charge state of a sample. In addition, an electrostatic charge during an analysis and/or processing process cannot always be determined with the necessary accuracy in advance. This complicates computer-aided correction of beam deflections caused by charges accumulated in the sample.

U.S. Pat. No. 6,734,443 B2 describes a method for removing contamination and for controlling a local electrostatic discharge in a process for manufacturing semiconductor components, for example photolithographic masks. For this purpose, a mask and a pellicle are placed in a chamber filled with an inert gas, and the individual components are irradiated with ultraviolet (UV) radiation before they are assembled. For EUV masks, this is in the wavelength range from 1 nm to 157 nm, and for masks whose actinic wavelength is 157 nm, it is in the range from 157 nm to 206 nm.

To minimize the effect of a drift of the particle beam relative to a non-conductive sample, such as a transmissive photomask, during a processing process of and/or during data acquisition from a site to be analyzed, one or more reference structures (drift markers)—as explained in US 2012/0273458 A1—are often placed near a defective sample site and are regularly imaged during the imaging and/or processing process. The measured deviations are used to correct the beam position (DC for drift correction). Generally speaking, the particle dose used to repair sample defects is different from the particle dose used to analyze reference structures and/or defective sample structures. If the site to be repaired and the reference structures are not electrically connected to one another, different amounts of charge are generated at the different sites, and so the beam deflection detected at the reference sites does not match the beam deflection at the processing site.

DE 10 2021 210 019.8 from the Applicant alleviates this problem by depositing an electrically conductive layer or protective layer around a defective site, which layer is electrically conductively connected to reference structures or drift markers that are used to correct a drift between the particle beam and the defective site. The conductive protective layer acts as a capacitor here. However, this gives rise to the undesirable effect of a deposited amount of charge that increases over time. This occurs in particular in photomasks that do not have continuous electrically conductive surface structures, such as masks for the ultraviolet (UV) and vacuum ultraviolet (VUV) wavelength range. If the electric field accompanying the electrostatic charge exceeds a predefined limit value, the forces acting on the particle beam become so great that the resulting effects, for example the beam deflection or the apparent change in the size of the field of view, are no longer able to be tolerated, since the processing and/or analysis of the sample is no longer able to be performed within the predefined specification of the device in question.

EUV masks, that is to say masks for the extreme ultraviolet (EUV) wavelength range, on the other hand contain flat regions of electrically conductive material, such as metal absorber elements on a metal capping layer and Bragg mirrors comprising molybdenum (Mo) layers. In these connected metal regions, introduced charges are able to be stored in delocalized fashion, in contrast to local accumulation in electrically non-conductive materials, such as quartz substrates of transmissive photomasks. EUV masks may thereby act like capacitors. The electric field generated by electric charges may interfere with the imaging and/or processing of EUV masks with charged particle beams. This aspect is described in application DE 10 2019 200 696 A1 from the Applicant.

Direct electrical contacting of EUV masks, that is to say grounding thereof, is generally problematic, as this could damage the photomask. Furthermore, the structures on EUV masks in the border region are often interrupted by what are known as black borders, meaning that it is not known, a priori, at which site electrical contact is to be made.

The present invention is therefore based on the problem of improving the known approaches for imaging and/or processing samples, in particular for samples in the form of lithographic masks having defects.

### SUMMARY

This problem is at least partly solved by the various aspects of the present invention.

According to one aspect, a method for setting an electrostatic charge of a sample comprises: (a) adjusting at least one parameter of at least one particle beam such that, on average, each particle, incident on the sample, of the at least one particle beam releases a predefined average number of electrons from the sample; (b) irradiating the sample with the at least one adjusted particle beam at at least one first site in order to set the electrostatic charge of the sample; (c) readjusting at least one parameter of the at least one particle beam and/or adjusting at least one other particle beam in order to analyze and/or process at least one second site of the sample; and (d) irradiating the at least one second site of the sample with the readjusted at least one particle beam and/or the adjusted at least one other particle beam, wherein the at least one first site and the at least one second site are at a predefined distance and are electrically conductively connected to one another.

Setting an electrostatic charge and processing a sample at two different sites or positions of the sample makes it possible to avoid complex superposition of two particle beams on the sample that differ in terms of at least one parameter. In addition, the spatial separation between the setting of the charge and the processing opens up new process control possibilities. In the case of simultaneous irradiation with a first particle beam in order to set the charge distribution and a second particle beam in order to process a defective sample, one or more parameters of the first and second particle beam may be changed without this affecting the points at which the particle beams are incident on the sample. Setting an electrostatic charge of a sample has substantially no effect on the analysis and/or processing thereof. In addition, the electrostatic charge may be set by way of an adjusted particle beam such that the adjusted particle beam substantially does not damage the sample to be processed.

Furthermore, the method according to the invention indicated above may be carried out with a single particle beam by setting the electrostatic charge of the sample and analyzing and/or processing it in succession. Particularly advantageously, a method according to the invention may be used to analyze and/or process electrically conductive samples. Here, the spatial separation between the setting of the electrostatic charge and the analysis and/or processing may be implemented without the effort of carrying out a further process step.

Steps b. and d. of the above method according to the invention may be carried out simultaneously.

The two particle beams do not have to be superimposed here. This allows the described method to be carried out with ease. In addition, the at least one parameter of the first particle beam may be set independently of the at least one parameter of the second particle beam.

Steps b. and d. of the above method according to the invention may be carried out sequentially.

A spatial or a local distance between the points on which the particle beam that sets the electrostatic charge of an electrically conductive sample and that analyzes and/or processes the sample is incident thus additionally allows greater flexibility in the time dimension. This makes it possible to use a device with a single particle beam to analyze or process a sample with at the same time controlled electrostatic charge. This enables a significant reduction in complexity of a device that carries out a method according to the invention.

A processing particle beam may have a lower kinetic energy of its particles than an analyzing particle beam. The electrostatic charge of the sample (to be processed) may be set individually, both for the processing particle beam and for the analyzing particle beam.

An analyzing particle beam may image this by scanning a sample, in particular a second site. A second site, or a site to be processed, may comprise a defective site or a defect in the sample.

The at least one particle beam may irradiate the at least one first site with a first adjustment, irradiate the at least one second site with a second adjustment for processing purposes and irradiate the at least one second site with a third adjustment for analysis purposes.

This means that the particle beam setting an electrostatic charge of the sample surface may be adjusted such that carrying out processing with a second adjustment and analysis with a third adjustment of the particle beam does not exceed a predefined electrostatic potential.

It is also possible for the at least one particle beam to irradiate at least one first site with a first adjustment and to irradiate the at least one second site with a second adjustment in order to analyze them and for the at least one particle beam to irradiate the at least one first site with a third adjustment and to irradiate the at least one second site with a fourth adjustment in order to process them.

The at least one particle beam may irradiate the at least one first site with a first adjustment and the at least one other particle beam may irradiate the at least one second site with a first adjustment in order to process them, or the at least one particle beam may irradiate the at least one first site with a second adjustment and the at least one other particle beam may irradiate the at least one second site with a second adjustment in order to analyze them.

The predefined distance may be selected such that the irradiation of the at least one first site with the at least one particle beam at the predefined distance substantially does not affect the irradiation of the at least one second site with the at least one particle beam or the at least one other particle beam in order to analyze and/or process the at least one second site of the sample.

This means that the irradiation of the at least one site with the adjusted particle beam substantially does not have any influence on carrying out an adjacent local chemical reaction in order to process a defective site or in order to repair a defect in the sample by way of the at least one particle beam and/or the at least one other particle beam. Conversely, the adjacent carrying out of a local chemical reaction does not affect the setting of a predefined electrostatic charge of the site to be processed by irradiating the at least one site with the adjusted particle beam.

The predefined distance may comprise a minimum distance that must not be fallen below.

The predefined distance between the at least one first site and the at least one second site may comprise at least a length or a width of a scan region of the at least one particle beam.

If the length and width of the scan region have different numerical values, the predefined distance refers to the size with the smaller numerical value.

The scan region of the particle beam may encompass a region of 4 μm·4 μm, preferably 8 μm·8 μm, more preferably 12 μm·12 μm, and most preferably 20 μm·20 μm. The predefined distance may exceed a length or a width of the scan region by a factor of 2, preferably a factor of 10, more preferably a factor of 100, and most preferably a factor of 500.

The irradiation of the at least one second site in order to process the at least one second site may comprise: providing at least one precursor gas at the at least one second site. The at least one second site may comprise a defect in the sample to be processed. The at least one precursor gas may comprise at least two elements from the following group: a deposition gas, an etching gas or an additive gas. The processing of at least one second site may comprise initiating a local chemical reaction of the at least one precursor gas by way of the particle beam and/or the other particle beam.

At the at least one first site, a concentration of the at least one precursor gas may be less than 50%, preferably less than 10%, more preferably less than 1%, and most preferably less than 0.1% of a maximum concentration at the at least one second site to be processed.

An occupancy density of the at least one precursor gas at the at least one first site may be less than 50%, preferably less than 10%, more preferably less than 1%, and most preferably less than 0.1% of a maximum occupancy density at the second site to be processed. An occupancy density describes the number of adsorbed precursor gas molecules per unit area (e.g. number per cm²).

The predefined distance between the at least one first site and the at least one second site may be at least 20 μm, preferably at least 200 μm, more preferably at least 2 mm, and most preferably at least 10 mm.

A method according to the invention may furthermore comprise: depositing an electrically conductive sacrificial layer on the at least one second site of the sample by way of the at least one particle beam and at least one precursor gas. The deposition of the electrically conductive sacrificial layer may take place at least around part of the site to be processed or around a defect to be processed.

The deposition of an electrically conductive sacrificial layer around at least part of a site to be processed makes it possible—in addition to protecting the sample in the region of the defective site during processing thereof—to set an electrostatic charge in the region of the second site, to be processed, of an electrically insulating sample at a predefined distance from the site to be processed.

A method according to the invention may furthermore comprise: depositing at least one drift marker adjacent to the site to be processed by way of the at least one particle beam and at least one precursor gas. The at least one drift marker may be deposited on the electrically conductive sacrificial layer.

In addition, a method according to the invention may comprise: determining a reference position of the at least one drift marker before starting processing of the at least one defective site.

A method according to the invention may furthermore comprise: interrupting the irradiation of the at least one particle beam or of the at least one other particle beam for processing the at least one second site; determining a position of the at least one drift marker; determining a deviation of the determined position of the at least one drift marker from a reference position; correcting a position at which the at least one particle beam or the at least one other particle beam is incident on the at least one second site by the ascertained deviation; and continuing the irradiation with a corrected particle beam in order to process the at least one second site.

The interruption of the processing and the correction of a drift of the at least one particle beam may be repeated at regular or irregular time intervals. The iterative processing of a second site to be processed may be continued until a remaining defect residual of the site to be processed is less than a predefined threshold.

According to a second aspect, a method for setting an electrostatic charge of a sample comprises: (a) adjusting at least one parameter of at least one particle beam such that, on average, each particle, incident on the sample, of the at least one particle beam releases a predefined average number of electrons from the sample; and (b) irradiating the sample with the at least one adjusted particle beam in order to set the electrostatic charge of the sample.

A method according to the invention does not require any direct electrical contacting of the sample and thereby avoids the associated outlay, and in particular the associated risks. Furthermore, the described method allows not only controlled discharging of the electrostatic charge of a sample, but also allows controlled setting of a defined electrostatic charge of a sample surface. In addition, setting, refining or tuning an electrostatic charge does not affect the analysis of the sample, such as the imaging and/or processing thereof. In addition, accumulated charge may be removed from an electrically non-conductive sample, such as for example a transmissive photomask, in a controlled manner. Furthermore, the described method has the advantage that a particle beam that is already used for analyzing and/or processing the sample may additionally also be used to set a defined electrostatic charge. In addition, the particle beam may also be used to ascertain the size and mathematical sign of the electrostatic charge. The outlay in terms of equipment for carrying out a method according to the invention is therefore low.

Finally, the contactless setting of an electrostatic charge may advantageously be used in the repair of lithographic masks. The electrostatic charge, generated by an inspection step, of a mask may thus be set to a desired potential or potential level before carrying out a defect repair process. After the repair process has been carried out, the electrostatic charge of the mask may be determined and set to a level that does not affect the subsequent inspection process for checking the success of the repair.

The electrostatic charge of the sample may be set in a contactless manner.

The irradiation of the sample may comprise at least one of the following: focusing the at least one particle beam with a first adjustment on the sample and directing at least one flat-extending particle beam with a second adjustment onto the sample.

A sample may be analyzed and/or processed using a focused particle beam. This is also referred to as a “writing gun” in the specialist field. The adjustment of the at least one particle beam when analyzing the sample may differ from the adjustment of the at least one particle beam when processing the sample. The analysis and the processing of a sample may thus lead to different electrostatic charges. The alignment of a flat-extending adjusted particle beam corresponds to the effect of a flood gun on the site to be analyzed or processed. This makes it possible to set the electrostatic charge of the region under examination or processed region of the sample to a desired potential level.

The adjustment of the at least one parameter of the at least one particle beam and/or of the at least one other particle beam may comprise changing at least one parameter from the following group: a landing energy of the particles, incident on the sample, of the at least one particle beam and/or of the at least one other particle beam, a wavelength of the particles, incident on the sample, of the at least one particle beam, a flux density of the particles, incident on the sample, of the at least one particle beam and/or of the at least one other particle beam, and an irradiation time of the particles, incident on the sample, of the at least one particle beam and/or of the at least one other particle beam.

The flux density, the irradiation area and the irradiation time of the particles, incident on the sample, of the at least one particle beam and/or of the at least one other particle beam determine the irradiation dose applied by the at least one particle beam. The irradiation dose may be applied to a site of the sample through a single irradiation operation for a period of time that is determined by the irradiation dose. The treatment dose may also be applied in partial doses through periodic irradiation. The at least one particle beam, in order to apply a predefined irradiation dose in a region of a sample, may be scanned over same. The beam spot of the at least one particle beam may be adapted to that region of the sample to be irradiated.

A particle beam the energy of which is great enough to release electrons from the sample may cause electrostatic charging of a sample, in particular of an electrically non-conductive sample or of an electrically conductive non-grounded sample. If the beam incident on the sample, which beam is also referred to below as primary beam, contains electrically neutral particles, such as photons and/or atoms, an electrically insulating sample is always positively electrostatically charged. Since the primary beam is not supposed to have a destructive effect on the sample during examination and/or processing of the sample, that is to say a sputtering effect is undesirable, the photons and/or atoms of the primary beam primarily generate free electrons in the sample. Some of these electrons may leave the sample as secondary particles. In addition to photons of various wavelengths, secondary particles in particular include secondary electrons (SE) and/or backscattered electrons (BSE) that are used to detect an electrostatic sample charge. The SE and BSE leaving the sample result in a positive charge excess of the sample irradiated by the electrically neutral primary beam. This may for example be reduced or compensated for by irradiation with an electron beam the electrons of which have a corresponding landing energy.

A primary beam comprising electrically neutral or positively charged particles generates SE, but not BSE. Typically, BSE are generated only when the primary beam comprises electrons. This should be taken into consideration when the release of SE and BSE by a particle beam is mentioned below.

The charge balance when a sample is irradiated with a primary beam containing (positively charged) ions is likewise positive. As a result of the ions in the primary beam, the latter introduces positive charges into the sample, and the BSE and SE additionally remove negative charges from the sample, as a result of which said sample is positively electrostatically charged. The positive charge excess may be set for example by irradiation with electrons having an appropriately adjusted landing energy.

If negatively charged particles, such as electrons, are used in the primary beam, the charge balance of the sample may turn out to be positive, negative or neutral, depending on whether on average more or less than one secondary particle (sum of BSE and SE) is able to leave the sample per negatively charged particle, incident on the sample, of the primary beam.

The charge balance of the sample when irradiated with particle beams that have a mass depends on the landing energy of the particles on the sample. At a very low landing energy, the particles that have a mass of the primary beam release on average less than one secondary particle (BSE and SE) per incident primary particle, resulting in a low electrostatic charge of the sample, the mathematical sign of which is determined by the charge of the particles of the primary beam. As landing energy increases, the number of SE and BSE able to leave the sample increases, as therefore also does the electrostatic charge thereof. As described above, the mathematical sign of the electrostatic sample charge may be reversed depending on the charge of the particles of the primary beam.

In the case of electrons, which are often used as primary beams, the charge balance is negative for low landing energies, and a sample is negatively electrostatically charged. In an average landing energy range, an electron of the primary beam generates on average a total of more than one SE and BSE, and the sample is positively electrostatically charged. At high landing energies of the electrons of the primary beam, the generation rate of SE and BSE decreases again, and so the electric charge introduced into the sample by the electrons of the primary beam dominates the charge balance.

The at least one parameter of the at least one particle beam and/or of the at least one other particle beam may depend on a material composition of an irradiated area of the sample and/or on a surface contour of the irradiated area of the sample. On the one hand, the atomic number of the material or the material composition of the sample to be analyzed or to be processed influences the SE and/or BSE generation rate of a primary beam. On the other hand, edges and/or spikes on a surface in particular locally increase the SE generation rate of a primary beam. The SE yield of a sample or of a solid is determined by its electrical structure, the energetic position of the valence and conduction bands, the Fermi level and the discharge work that SE have to overcome on the surface.

If photons are used as primary beams, there is a threshold for their wavelength starting from which the light quanta are able to release electrons from their bonds in the sample. As wavelength decreases, that is to say as energy increases, their electron release rate, that is to say their SE generation rate or their yield coefficient, increases. If photons have a wavelength that is smaller than the limit wavelength, the SE generation rate additionally depends on the flux density at which the primary beam is incident on the sample. This means that, the greater the beam strength of a photon beam (above the energy threshold), the larger the SE beam generated by the sample.

The adjustment of the at least one parameter of the at least one particle beam may comprise at least one element from the following group: setting a fixed numerical value, setting a range of values through which the at least one parameter passes at least once during the irradiation of the sample, and shifting the range of values.

The at least one parameter may pass through the range of values linearly or non-linearly. Furthermore, the at least one parameter of the at least one particle beam may oscillate within the range of values. The amplitude of the oscillation may be constant or may vary within the predefined range of values.

Setting a range of values for the at least one parameter makes it possible to experimentally ascertain an optimum numerical value for the at least one parameter.

This procedure may be advantageous if the material composition and/or the contour of the sample is not known, or is not known in detail. Furthermore, this procedure may be advantageous if the effect of a particle beam on the sample is not sufficiently known.

The adjustment of the at least one parameter may furthermore comprise at least one of the following: determining a current strength and/or a flux density of the at least one particle beam and determining an irradiation time of the sample with the at least one particle beam and/or the at least one other particle beam.

In addition to the landing energy, the current strength or the flux density of the at least one particle beam determines the electric charge q(t) generated per unit of time by the particle beam in the sample. The charge accumulated in the sample over the irradiation time t₂−t₁ gives the electrostatic charge

$$Q ( {t}_{2} ) = {\int }_{{t}_{1}}^{{t}_{2}} q ( t ) dt + Q ( {t}_{1} ) .$$

For t→∞ an equilibrium value Q(t→∞) is established for the accumulated charge. If the sample is an electrical insulator, the charge accumulates locally. This may lead to a large local electrostatic charge, with the accompanying high electric field strengths.

The irradiation with a first adjustment of the at least one parameter of the at least one particle beam may positively/negatively electrostatically charge the sample, and the irradiation with a second adjustment of the at least one parameter of the at least one particle beam may negatively/positively electrostatically charge the sample.

By way of example, the sample may be analyzed or imaged with a higher landing energy of a primary beam in order to increase the lateral spatial resolution of the particle beam that is used. If the primary beam uses electrons and the sample to be analyzed comprises a photomask, it is possible to use a kinetic energy >2 keV, for example 2 keV to 5 keV, 2 keV to 4 keV, 2.5 keV to 3.5 keV or around 3 keV for an imaging process, as the landing energy of the electrons. In order to optimize the lateral spatial resolution of a local particle beam-induced chemical reaction, it is possible to use an electron landing energy in the range of 20 eV to 2500 eV, 40 eV to 2000 eV, 70 eV to 1500 eV, 100 eV to 1100 eV, 150 eV to 800 eV, 200 eV to 600 eV for a repair process.

The analysis and/or processing of the sample with the at least one particle beam may lead to different electrostatic charges, since both processes may use different landing energies of the particles of the primary beam. The electrostatic charge of the sample may be set before or after the sample is imaged with an adjustment of the at least one parameter of the at least one particle beam that is different from the adjustment of the at least one parameter of the at least one particle beam in order to set the electrostatic charge after a processing process has been carried out.

The irradiation of the sample with a second adjustment of the at least one parameter of the at least one particle beam may substantially compensate for the electrostatic charge of the sample generated by the irradiation of the sample with a first adjustment of the at least one parameter of the at least one particle beam.

As a special case of setting an electrostatic charge, the second adjustment of the at least one particle beam may be tuned such that, by irradiating the sample with the second adjustment of the at least one parameter, the electrostatic charge of the sample caused by the first adjustment of the at least one parameter is compensated for.

The term “substantially” here means—as in other places of this application—an indication of a measured quantity within the customary error limits, with metrology according to the prior art being used to measure the quantity.

The at least one particle beam may comprise particles from the following group: electrons, ions, atoms, molecules and high-energy photons. At present, electrons are preferably used both to analyze a sample and to process it. Electrons at present offer the best possible compromise between precise imaging and processing of a sample, on the one hand, and damage to the sample caused by electron bombardment, on the other hand.

High-energy photon sources have the advantage that they are not affected by an electrostatic sample charge.

The particle beam may comprise electrons, and the at least one parameter of the at least one particle beam may comprise the landing energy of the electrons on the sample. The landing energy of the electrons, or generally of electrically charged particles, may be set by selecting the acceleration voltage of the charged particles and/or by applying a braking voltage just above the sample surface. A braking voltage for charged particles of a particle beam may be generated by applying an electrostatic potential to a metal tube mounted in the column output of a particle-optical column, which metal tube is referred to as a “liner tube” in the specialist field. If a screening grid is mounted on the column output of a scanning particle microscope, the braking voltage for a charged particle may be set by applying a corresponding potential between the screening grid and the metal tube.

The high-energy photons may have an energy sufficient to release electrons from their bonds in the material of the sample when said photons are absorbed by the sample. Photons from the VUV and in particular from the EUV wavelength range of the electromagnetic spectrum have enough energy to do this.

A method according to the invention may furthermore comprise providing at least one precursor gas at a processing site of the sample during the irradiation of the sample with the at least one adjusted particle beam.

A defect in a sample may be repaired by carrying out a particle beam-induced local chemical reaction with the aid of at least one precursor gas. In the event of a missing-material defect (clear defect), at least one precursor gas in the form of a deposition gas may be provided at the defect location. In the event of an excess-material defect (dark defect), at least one precursor gas in the form of an etching gas may be provided at the defect location. In addition to at least one etching gas and/or at least one deposition gas, the at least one precursor gas may comprise at least one additive gas.

The at least one deposition gas may comprise at least one element from the group: a metal alkyl, a transition element alkyl, a main group alkyl, a metal carbonyl, a transition element carbonyl, a main group carbonyl, a metal alkoxide, a transition element alkoxide, a main group alkoxide, a metal complex, a transition element complex, a main group complex and an organic compound.

A metal alkyl, a transition element alkyl and a main group alkyl may comprise at least one element from the group: cyclopentadienyl (Cp) trimethyl platinum (CpPtMe₃), methylcyclopentadienyl (MeCp) trimethyl platinum (MeCpPtMe₃), tetramethyltin (SnMe₄), trimethylgallium (GaMe₃), ferrocene (Cp₂Fe) and bisarylchromium (Ar₂Cr). A metal carbonyl, a transition element carbonyl and a main group carbonyl may comprise at least one element from the group: chromium hexacarbonyl (Cr(CO)₆), molybdenum hexacarbonyl (Mo(CO)₆), tungsten hexacarbonyl (W(CO)₆), dicobalt octacarbonyl (CO₂(CO)₈), triruthenium dodecacarbonyl (Ru₃(CO)₁₂) and iron pentacarbonyl (Fe(CO)₅). A metal alkoxide, a transition element alkoxide and a main group alkoxide may comprise at least one element from the group: tetraethyl orthosilicate (TEOS, Si(OC₂H₅)₄) and tetraisopropoxytitanium (Ti(OC₃H₇)₄). A metal halide, a transition element halide and a main group halide may comprise at least one element from the group: tungsten hexafluoride (WF₆), tungsten hexachloride (WClI), titanium hexachloride (TiCl₆), boron trichloride (BCl₃) and silicon tetrachloride (SiCl₄). A metal complex, a transition element complex and a main group complex may comprise at least one element from the group: copper bis(hexafluoroacetylacetonate) (Cu(C₅F₆HO₂)₂) and dimethylgold trifluoroacetylacetonate (Me₂Au(C₅F₃H₄O₂)). The organic compounds may comprise at least one element from the group: carbon monoxide (CO), carbon dioxide (CO₂), aliphatic hydrocarbons, aromatic hydrocarbons, constituents of vacuum pump oils and volatile organic compounds.

The at least one etching gas may comprise one element from the group: a halogen-containing compound and an oxygen-containing compound. The halogen-containing compound may comprise at least one element from the group: fluorine (F₂), chlorine (Cl₂), bromine (Br₂), iodine (I₂), xenon difluoride (XeF₂), dixenon tetrafluoride (Xe₂F₄), hydrofluoric acid (HF), hydrogen iodide (HI), hydrogen bromide (HBr), nitrosyl chloride (NOCI), phosphorus trichloride (PCl₃), phosphorus pentachloride (PCI₅) and phosphorus trifluoride (PF₃). The oxygen-containing compound may comprise at least one element from the group: oxygen (O₂), ozone (O₃), water vapour (H₂O), hydrogen peroxide (H₂O₂), nitrous oxide (N₂O), nitrogen oxide (NO), nitrogen dioxide (NO₂) and nitric acid (HNO₃).

The at least one additive gas may comprise at least one element from the group: an oxidizing agent, a halide and a reducing agent.

The oxidizing agent may comprise at least one element from the group: oxygen (O₂), ozone (O₃), water vapour (H₂O), hydrogen peroxide (H₂O₂), nitrous oxide (N₂O), nitrogen oxide (NO), nitrogen dioxide (NO₂) and nitric acid (HNO₃). The halide may comprise at least one element from the group: chlorine (Cl₂), hydrochloric acid (HCl), xenon difluoride (XeF₂), hydrofluoric acid (HF), iodine (I₂), hydrogen iodide (HI), bromine (Br₂), hydrogen bromide (HBr), nitrosyl chloride (NOCl), phosphorus trichloride (PCl₃), phosphorus pentachloride (PCl₅) and phosphorus trifluoride (PF₃). The reducing agent may comprise at least one element from the group: hydrogen (H₂), ammonia (NH₃) and methane (CH₄).

An electrically conductive sacrificial layer may be deposited by providing the precursor gas Mo(CO)₆ and the additive gas NO₂. Sacrificial layers deposited in this way may be removed by mask cleaning.

An electrically conductive sacrificial layer allows spatial separation of the setting of an electrostatic charge from analysis or processing of a sample. In addition, setting an electrostatic charge of the sample by way of an electrically conductive sacrificial layer minimizes sample damage caused by irradiation thereof.

A lateral extent of a local particle beam-induced chemical reaction for depositing material and for locally removing material from a sample may be in the range of <10 nm, preferably <7 nm, and most preferably <5 nm. An edge placement error of a pattern element of a lithographic mask should, when it is measured and/or after it has been repaired, be <2.1 nm, preferably <1.4 nm, and most preferably <1.0 nm. The placement of a pattern element of a lithographic mask may be measured with a repeatability of 0.5 nm or better. The accuracy thereof is in the region of 1 nm or less.

The at least one particle beam may comprise at least one first particle beam and at least one second particle beam.

A method according to the invention may furthermore comprise: analyzing and/or processing the sample with the at least one second adjusted particle beam and setting the electrostatic charge of the sample by way of the at least one first adjusted particle beam.

In addition, the described method may comprise: imaging the sample with the at least one first particle beam with a first adjustment and setting the electromagnetic charge of the sample by way of the at least one second particle beam with a first adjustment and processing the sample with the at least one first particle beam with a second adjustment and setting the electromagnetic charge of the sample by way of the at least one second particle beam with a second adjustment.

The at least one first particle beam may comprise a focused adjusted particle beam that is used to image and/or process the sample with the best possible lateral spatial resolution. The at least one parameter of the at least one first particle beam may be adapted to the function to be carried out by the particle beam. By way of example, the analysis of the sample may be carried out with a greater landing energy of the charged particles of the particle beam than the processing of the sample. Furthermore, the at least one second particle beam may be a particle beam from a flood gun. The flood gun may use the same particle type as the at least one first particle beam. However, it is also possible for the at least one first and the at least one second particle beam to use particles the electric charge of which has a different mathematical sign. By way of example, the at least one first particle beam may use electrons and the flood gun may use (positively charged) ions, or vice versa.

A method according to the invention may furthermore comprise: focusing the at least one first particle beam with a first adjustment of the at least one parameter on the sample and directing the at least one second particle beam with a second adjustment of the at least one parameter with a flat extent onto the sample.

In addition, a method according to the invention may comprise: scanning the at least one first focused particle beam with a first adjustment of the at least one parameter over the sample within an area that is irradiated by the at least one second particle beam with a second adjustment of the at least one parameter.

The at least one first particle beam and the at least one second particle beam may use the same particle type, such as electrons. However, it is also possible for the at least one first particle beam and the at least one second particle beam to use different particle types. By way of example, the at least one first particle beam may comprise photons and the at least one second particle beam may comprise electrons.

A method according to the invention may furthermore comprise: simultaneously irradiating the sample with the at least one first particle beam with a first adjustment of the at least one parameter and the at least one second particle beam with a second adjustment of the at least one parameter. The second adjustment of the at least one second particle beam may be tuned to the first adjustment of the at least one first particle beam. The at least one first particle beam and the at least one second particle beam may comprise electrons, and the first adjustment of the at least one parameter of the at least one first particle beam and the second adjustment of the at least one parameter of the at least one second particle beam may together lead to a yield coefficient of one, that is to say, on average, a particle of the first particle beam and a particle of the second particle beam release two electrons from the sample. Irradiating a sample with two or more electron beams adjusted in this way does not change its electrostatic charge.

In addition, a method according to the invention may comprise: electrically connecting a second site, to be analyzed and/or to be processed, of the sample to at least one first site of the sample, wherein the second site to be analyzed and/or to be processed and the at least one first site are at a predefined distance from one another.

Electrically conductively connecting at least one first site of the sample to the second site to be analyzed or to be processed means that the setting of the electrostatic potential distribution is able to take place at any location on the sample. In particular, the at least one first site may be selected at a location on the sample at which a particle irradiation does not affect the function of the sample.

An electrically conductive connection between the second site to be analyzed and/or to be processed and the at least one first site may be created by depositing a conductive layer on the sample with the aid of at least one adjusted particle beam and at least one precursor gas that contains at least one deposition gas.

The at least one site, to be analyzed and/or to be processed, of the sample may be irradiated with the at least one second adjusted particle beam, and the at least one first site of the sample may be irradiated with the at least one second adjusted particle beam.

A method according to the invention may comprise simultaneously irradiating the second site to be analyzed and/or to be processed and the at least one first site of the sample. At least one second adjusted particle beam may irradiate the second site, to be analyzed or to be processed, of the sample, and at least one first adjusted particle beam may simultaneously irradiate the at least one first site of the sample. In this embodiment, it is possible to ensure that the sample has a predetermined electrostatic charge while examining the sample and/or during a processing process of the sample. Adjusting the at least two particle beams in relation to one another in particular makes it possible to examine or process a sample such that it has substantially no electrostatic charge. If the at least one parameter of the at least one second particle beam is adapted upon the transition from an analysis process to a processing process, the at least one parameter change of the at least one second particle beam may be compensated for by a corresponding parameter adaptation of the at least one parameter of the at least one first particle beam.

An electrostatic charge, to be compensated for, of the sample may encompass a voltage range of −5000 V to +5000 V, −1000 V to +1000 V, −200 V to +200 V, or −50 V to +50 V.

An adjusted particle beam may be used to set an electrostatic charge of a sample that encompasses a voltage range of −3000 V to +3000 V, −1000 V to +1000 V, or −500 V to +500 V.

If the primary beam comprises an electron beam, the electrons thereof for setting an electrostatic charge may comprise a landing energy in the range of 10 V to 5000 V, preferably 20 V to 4000 V, more preferably 30 V to 3000 V, and most preferably 50 V to 2000 V.

The sample may comprise an element from the following group: a lithographic mask, a nano-imprint lithography die stamp, a wafer, an integrated circuit (IC), a MEMS (micro-electromechanical system), a NEMS (nano-electromechanical system) and a PIC (photonic integrated circuit). The lithographic mask may comprise a transmissive or reflective photomask. The mask may also comprise any type of mask.

The sample may comprise at least one defect around at least part of which an electrically conductive protective layer is placed, and the at least one second adjusted particle beam may irradiate the at least one defect and the at least one first adjusted particle beam may irradiate the electrically conductive protective layer. The sample having the at least one defect may comprise a lithographic mask. The at least one defect may comprise a missing-material defect and/or an excess-material defect.

The at least one particle beam may analyze and/or process the at least one defect with a first adjustment of the at least one parameter and may irradiate the electrically conductive protective layer with a second adjustment of the at least one parameter in order to set a predefined electrostatic charge of the sample in the region of the at least one defect.

The sample may comprise two or more drift markers that are not arranged on a straight line and therefore span a two-dimensional (2D) coordinate system. The displacements of the at least three drift markers relative to the reference positions thereof before the start of the analysis and/or processing process make it possible to ascertain a distortion of the imaging scale or a change in size of the 2D coordinate system caused by electrostatic charging of the sample surface.

A method according to the invention may furthermore comprise the following step: reducing the electrostatic charge of the sample by increasing a surface area of the electrically conductive protective layer. The capacitance of a capacitor is proportional to the surface area thereof on which electric charge is able to be stored. Increasing the surface area of the electrically conductive protective layer makes it possible to reduce the increase or extent of an electrostatic charge caused by irradiation with a particle beam able to release electrons from their bonds in the protective layer. A lower surface area charge density generates a lower electrostatic field strength, thus resulting in a smaller deflection of a charged particle beam.

A method according to the invention may furthermore comprise the following step: determining the electrostatic charge of the sample by way of at least one element from: a change in size of at least one reference structure of the sample or a drift correction of the at least one adjusted particle beam during analysis and/or processing of the sample.

Electrostatic charging of a sample leads to a change in the imaging scale. Depending on the type of charge, the at least one reference structure of the sample may be imaged larger or smaller by a charged particle beam. If the size of the at least one reference structure is known, for instance from data from the sample manufacturer or from measurements of the at least one reference structure with an uncharged particle beam, the absolute value and the mathematical sign of the electrostatic sample charge may be determined from the measured change in size of the at least one reference structure.

Reference elements in the form of drift markers are used to measure and to correct a drift between a second site to be analyzed or to be processed and a particle beam during an analysis or processing process. If two or more drift markers are used for this purpose around a second site, to be analyzed or to be processed, of the sample, a change in size or a distortion of the imaging scale may be determined from the changes in position of the two or more drift markers, in addition to a drift of the particle beam relative to the drift markers. This may be used to ascertain the size and the mathematical sign of an electrostatic sample charge.

A method according to the invention may furthermore comprise: analyzing at least one defect with at least one adjusted particle beam, processing the majority of the defect with the at least one particle beam, and processing a remaining defect residual with the at least one adjusted particle beam. This means that a defect residual, in particular comprising the borders of the defect, is analyzed and processed without the influence of an electrostatic charge of the sample, whereas, during the processing of the majority of the defect, no attention is paid to an electrostatic charge of the sample surface. This process control makes it possible to speed up defect repair without reducing the precision thereof.

A method according to the invention may furthermore comprise the following step: electrostatically charging the sample within a predefined potential interval by irradiation with the at least one particle beam with a first adjustment before processing and/or analyzing the sample, in particular at least one defect in the sample. The sample is then analyzed and/or processed with a second adjustment of the at least one parameter of the at least one particle beam. The irradiation of the sample with the second adjustment of the at least one parameter causes it to be electrostatically charged with a mathematical sign that is opposite to the electrostatic charging of the sample brought about by irradiation with the first adjustment of the at least one parameter of the at least one particle beam. A potential interval may comprise an electrical potential interval. An electrical potential interval may comprise a voltage.

The methods defined in this application open up the possibility of charging a sample, in a defined and controlled manner, to a voltage level that does not interfere with subsequent analysis and/or subsequent processing by irradiation with a charged particle beam. This means that the deflections of a charged particle beam remain below a tolerable threshold. Selecting the mathematical sign of the controlled electrostatic charge makes it possible to double a processing time before the electrostatic charge of the sample caused by the processing process has a noticeable influence on the analysis or processing process.

A computer program stored in a non-volatile memory may contain instructions that cause a computer system to carry out the method steps of one of the aspects described above.

According to a further aspect, a device for setting an electrostatic charge of a sample has: (a) means for adjusting at least one parameter of at least one particle beam such that, on average, each particle, incident on the sample, of the at least one particle beam releases a predefined average number of electrons from the sample; (b) means for irradiating the sample with the at least one adjusted particle beam at at least one first site in order to set the electrostatic charge of the sample; (c) means for readjusting at least one other particle beam in order to analyze and/or process at least one second site of the sample; and (d) means for irradiating the at least one second site of the sample with the readjusted at least one particle beam and/or the adjusted at least one other particle beam, wherein the at least one first site and the at least one second site are at (at least) a predefined distance and are electrically conductively connected to one another.

According to another aspect, a device for setting an electrostatic charge of a sample comprises: (a) means for adjusting at least one parameter of at least one particle beam such that, on average, each particle, incident on the sample, of the at least one particle beam releases a predefined average number of electrons from the sample; and (b) means for irradiating the sample with the at least one adjusted particle beam in order to set the electrostatic charge of the sample.

The device may be configured to carry out the method steps of the aspects described above.

The means for adjusting the at least one parameter of the at least one particle beam and/or of the at least one other particle beam may comprise at least one element from the following group: means for setting an acceleration voltage of the particles of the at least one particle beam and/or of the at least one other particle beam, means for setting a braking voltage of the particles of the at least one particle beam and/or of the at least one other particle beam, means for setting a wavelength of the particles of the at least one particle beam and/or of the at least one other particle beam, means for setting a flux density of the at least one particle beam and/or of the at least one other particle beam, or means for setting an irradiation time of the particles of the at least one particle beam and/or of the at least one other particle beam.

The means for setting an acceleration voltage may comprise setting an anode potential and/or a cathode potential of a particle source for charged particles. The means for setting a braking voltage may comprise setting a potential of a metal tube at the output of a particle-optical column of a scanning particle microscope. In addition, the means for setting the braking voltage may comprise setting a potential between a screening grid mounted on the column output and the metal tube (liner tube). The means for setting a wavelength of the particles of the at least one particle beam may comprise a broadband light source (for the VUV and/or EUV wavelength range) and one or more bandpass filters. The means for setting a wavelength may furthermore comprise a first light source that emits in a first wavelength range and comprise at least one second light source that emits in at least one second wavelength range that is different from the first wavelength range. The means for setting a flux density of the at least one particle beam may comprise setting a beam strength of the particle source and/or one or more absorption filters if the particle source comprises a photon source. The means for setting an irradiation time may comprise a beam blanker.

The device according to the invention may furthermore have at least one element from the following group: an electron flood gun, an ion flood gun, an adjustable diaphragm for the at least one particle beam, at least one second particle beam source for generating at least one second particle beam, or an energy-selective detector for secondary electrons and/or backscattered electrons.

The flood gun may comprise charged particles that have the same mathematical sign as the particles of the primary beam. The particles from the flood gun may be charged oppositely to the particles of the primary particle beam. The adjustable diaphragm may comprise a condenser diaphragm of a particle-optical column of a scanning particle microscope. An aperture width of the adjustable diaphragm may encompass a range of 1 nm to 1 mm, preferably 10 nm to 300 μm, more preferably 100 nm to 100 μm, and most preferably 1 μm to 50 μm. The adjustable diaphragm may comprise a diaphragm system consisting of two or more diaphragms. The diaphragm or the diaphragm system may be arranged behind (downstream of) the condenser of the particle-optical column of a scanning particle microscope. A second particle beam source makes it possible to process a sample by way of a second particle beam from a second particle beam source and to simultaneously set a predefined electrostatic charge of the sample by irradiating the at least one first site with a first particle beam from the at least one first particle beam source.

The energy-selective detector may comprise a spectrometer-detector combination having a filter or a filter system that discriminates SE and BSE according to their energy. Retarding field spectrometers, deflecting spectrometers using a magnetic field or an electrostatic field, for instance in the form of cylindrical deflection analyzers (CDA), may be used as spectrometers or energy filters, for example. It is also possible to use multi-channel spectrometers that are able to simultaneously determine substantially the entire energy spectrum of the SE and/or BSE.

The device according to the invention may furthermore have: means for displacing a point of incidence of the at least one particle beam from the at least one first site of the sample to the at least one second site, to be processed, of the sample.

A device according to the invention is able to provide the at least one particle beam in the form of at least one electron beam and is able to set the landing energy of the at least one electron beam such that the cumulative SE and BSE generation rate (in the example of the electron beam: per electron of the primary electron beam) is <1. This is the case for landing energies that are smaller than a first energy threshold E₁ and greater than a second energy threshold E₂. When the sample is irradiated with electron landing energies in these ranges, a sample is negatively electrostatically charged. As already explained above, the lowest possible landing energies of the electrons of an electron beam are advantageous for carrying out processing processes on lithographic masks, that is to say the energy range below E₁.

Within the energy interval E₁ to E₂, the sum of the yield coefficients for SE (δ) and BSE (η) is greater than 1, and a sample acquires a positive electrostatic charge. The electrostatic charging takes place more quickly the more the sum of the yield coefficients differs from 1. If the landing energy of the charged particles is able to be selected freely within a certain interval, it is advantageous to select this such that the sum of δ and η is as close as possible to 1. Conversely, if the sample is intended to be electrostatically charged in a controlled manner, it is advantageous for this purpose to select yield coefficients for SE and BSE the numerical values of which are as far away as possible from 1.

The at least one parameter may thereby be optimized with regard to different objectives. For example, in the case of imaging the sample, it may be helpful to scan the sample with the greatest possible lateral resolution, for which a greater landing energy is typically desirable. This results in yield coefficients for SE and BSE in the range of >1.5. When processing the sample, on the other hand, it may be advantageous to select the landing energy of the primary electrons to be as low as possible in order to minimize the lateral extent of the chemical reaction induced by the electron beam. For this landing energy of the electrons, the yield coefficients are typically in the range of ≤0.5. The different electrostatic charges of the sample may be set to a desired level by irradiating the sample with a second adjustment of the at least one parameter of the at least one electron beam within the landing energy interval E₁ to E₂. As an alternative and/or in addition, the sample may be irradiated with a low-energy ion beam the yield coefficients of which for SE and BSI are <1, where BSI stands for back-scattered ions. BSI occur in particular for ions with a small atomic number, whereas ions with a large or high atomic number are for the most part implanted in a sample.

The device described herein may furthermore comprise a gas provision system that is able to provide one or more precursor gases at a processing location on the sample. The gas provision system is able to set the gas flow, the partial pressure and the temperature of the one or more precursor gases.

A device according to the invention may furthermore have means for directing the at least one particle beam onto the sample. The device may furthermore have a means for receiving information about the at least one parameter of the at least one particle beam. The device may additionally have means for ascertaining at least one adjustment of the at least one parameter of the at least one particle beam. Moreover, the device may have means for adjusting the at least one parameter of the at least one particle beam.

The means for receiving information may have a user interface. For example, software or hardware or a mixture thereof may make it possible for the user of the device to provide information about the at least one parameter of the at least one particle beam. The device may then accordingly adjust the at least one parameter automatically with the aid of the determining means (for example a computer unit, a processor, etc.). A semi-automatic selection is also conceivable in which the device offers the user a selection of adjustment options for the at least one parameter of the at least one particle beam and/or the at least one other particle beam, which adjustment options are adapted for the respective process and/or the sample to be treated and are ultimately able to be selected from by the user.

A user of the device is able to use the user interface to provide data about the material composition and/or the surface contour of a sample. The device may take these data into consideration when determining the at least one parameter. Furthermore, the device may be designed to take the sample data into consideration when outputting the adjustment options to the user.

A device according to the invention may additionally have means for carrying out a form of repair by way of the at least one other particle beam at the at least one second site, wherein the means may furthermore be configured to irradiate the at least one first site with the at least one particle beam in order to set the electrostatic charge of the sample.

The device may furthermore comprise a database in which the material compositions and the surface contours of different samples are stored. The samples may have a code that stores the type of sample together with associated material and surface data. The device is able to read the code of the sample and ascertain, from the defect data, the best adjustment option for the at least one parameter.

The device may be designed such that the means for receiving information is able to receive information that identifies a first process as a diagnostic process and/or a second process as a repair process.

Provision may also be made for the device for setting an electrostatic charge of a sample not to have means for directing a particle beam onto the mask. This may be provided for example as a separate hardware apparatus that is intended to interact with an apparatus for directing the particle beam onto the sample, for example by way of a (software) interface for providing information about the at least one parameter of the at least one particle beam and/or the first and/or second process. In addition or as an alternative to a device for this purpose, provision may also be made for a corresponding computer program.

The devices described herein may generally be configured to perform the methods described herein. Conversely, all aspects described here with respect to the device may also be performed as method steps.

### BRIEF DESCRIPTION OF DRAWINGS

The following detailed description describes currently preferred exemplary embodiments of the invention with reference to following drawings, in which:

FIGS. 1A-1C schematically show the irradiation of an electrostatically uncharged lithographic mask with an electron beam, wherein the mask has a reference structure and a defect with four drift markers;

FIGS. 2A-2C schematically present the irradiation of the mask from FIGS. 1A-1C, wherein the mask has a positive electrostatic charge;

FIGS. 3A-3C schematically reproduce the irradiation of the mask from FIGS. 1A-1C, wherein the mask has a negative electrostatic charge;

FIG. 4 schematically illustrates the currents when irradiating an electrically conductive sample (on the left) and an electrically insulating sample (on the right) with a particle beam;

FIG. 5 schematically shows the sum of the yield coefficients δ and η of the secondary electrons (SE) and of the backscattered electrons (BSE) as a function of the particle energy of the primary beam;

FIG. 6 schematically reproduces an imaging process of an EUV mask with an electron beam and a processing process of the EUV mask with an electron beam and a precursor gas;

FIG. 7 schematically illustrates the setting of an electrostatic charge of the EUV mask from FIG. 6;

FIG. 8 schematically presents the simultaneous imaging/processing and setting of an electrostatic charge for the EUV mask from FIGS. 6 and 7 with two electron beams;

FIG. 9 schematically repeats the setting of an electrostatic charge of the EUV mask from FIG. 7, wherein the EUV mask has an electrically conductive sacrificial layer that is irradiated in order to set the electrostatic charge;

FIG. 10 schematically shows the setting of an electrostatic charge of a transmissive mask, wherein the transmissive mask has an electrically conductive sacrificial layer on which a reference structure in the form of a drift marker is present, wherein the sacrificial layer is irradiated in order to set the electrostatic charge;

FIG. 11 once again schematically reproduces the transmissive mask from FIG. 9, wherein a first electron beam analyzes or processes the mask and a second electron beam sets the electrostatic charge thereof;

FIG. 12 schematically shows the temporal profile of an electrostatic sample charge in the upper partial image, and schematically illustrates an envisaged charge with a predefined polarity in the lower partial image;

FIG. 13 presents a schematic section through a device according to the invention;

FIG. 14 illustrates a flowchart of a method according to the invention; and

FIG. 15 reproduces a flowchart of a further method according to the invention.

### DETAILED DESCRIPTION

Currently preferred embodiments of the methods according to the invention and of the devices according to the invention for setting an electrostatic sample charge are explained in more detail below with reference to the example of lithographic masks and a modified scanning electron microscope. However, methods according to the invention are not limited to the reflective and transmissive photomasks described below. On the contrary, they may be used to set the electrostatic charge of any microstructured samples, such as nano-imprint lithography die stamps, wafers, ICs, MEMS, NEMS and PICs. Furthermore, devices according to the invention are not limited to the examples described below. As will be recognized without difficulty by a person skilled in the art, instead of the modified scanning electron microscope under discussion, it is possible to use any scanning particle microscope that uses for example a focused ion beam and/or a focused photon beam as energy source.

Currently preferred embodiments of the present invention are explained in more detail below with reference to the drawings.

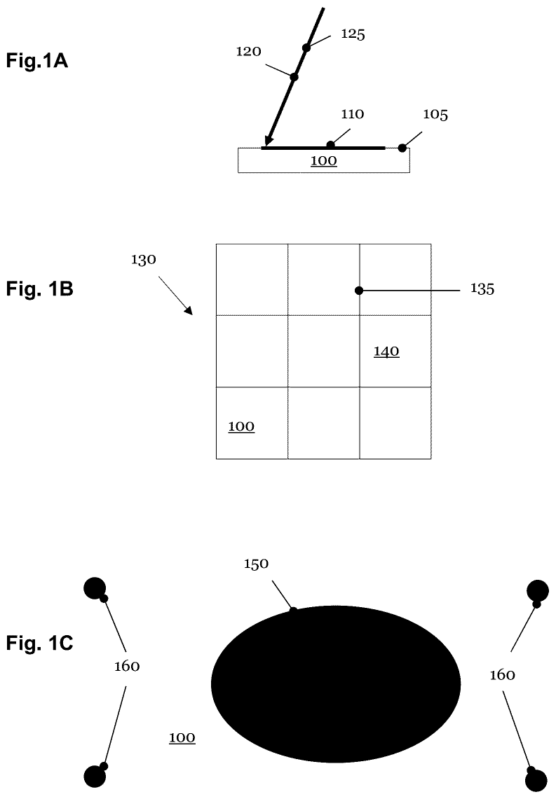

FIGS. 1A-1C show an exemplary lithographic mask 100 (hereinafter mask 100 for short) having a reference structure 130, a defect 150 and four reference elements 160, according to one example.

FIG. 1A shows a section through the mask 100, the surface 105 of which carries a pattern 110. The surface 105 or the pattern 110 are irradiated by an electron beam 120. The electron beam 120, as one example of a particle beam 120, is focused on the surface 105 of the mask 100 and scans the surface 105 of the mask 100 in order to acquire an image of the mask pattern 110. The landing energy of the electrons 125 of the electron beam 120 is normally selected such that the focus spot of the electron beam 120 on the mask 100 becomes minimal. The electron beam 120 thereby achieves a maximum lateral resolution. For this purpose, electron landing energies in the range of 3 keV are typically used.

However, it is also possible to acquire an image of a sample, such as the mask 100, with the landing energy of the electron beam 120 that is used to process the mask 100. This procedure avoids having to readjust the particle beam 120 or the electron beam 120 upon the transition from an analysis process to a processing process. In addition, in order to image a sample, the electron beam 120 may be scanned multiple times over the same region of the sample with different landing energies of the electrons 125 in order to increase the imaging quality.

FIG. 1B presents a schematic view of a reference structure 130 of the mask 100. The exemplary reference structure 130 of FIG. 1B is a square that is divided into nine sub-squares 140 by lines 135. The reference structure 130 may be arranged in a manner distributed over the mask 100 at regular or irregular intervals. As explained below, the reference structure 130 may be used to determine an electrostatic charge of the mask 100 or, generally, of a sample 100. As a rule, both the positions of the reference structures 130 and the size thereof are known from the manufacturer of the mask 100. If this is not the case, the positions and the size of the reference structures 130 may be determined using for example a mask inspection tool.

FIG. 1C reproduces a schematic view of a defect 150 in the mask 100. The exemplary defect 150 is an excess-material defect or a dark defect 150. Of course, the method described here may also be used for the precise imaging and/or repair of a missing-material defect or a clear defect 150. Four reference elements 160 in the form of drift markers 160 are deposited around the defect 150 in FIG. 1C. The drift markers 160 may be deposited on the mask 100 around the defect 150 with the aid of an electron beam-induced deposition process while providing at least one precursor gas in the form of a deposition gas. The drift markers 160 span a two-dimensional (2D) coordinate system. Three reference elements 160 that are not arranged on a straight line are sufficient for spanning a 2D coordinate system. The drift markers 160 are predominantly scanned periodically with the electron beam 120 during a repair process of the defect 150 in order to detect a drift of the defect 150 or of the drift markers 160 with respect to the reference positions of the drift markers 160. The change in the positions of the drift markers 160 with respect to their reference positions may also be used, in addition to determining a relative drift between the electron beam 120 and the drift markers 160 of the mask 100 or the defect 150, to ascertain an electrostatic charge of the mask 100.

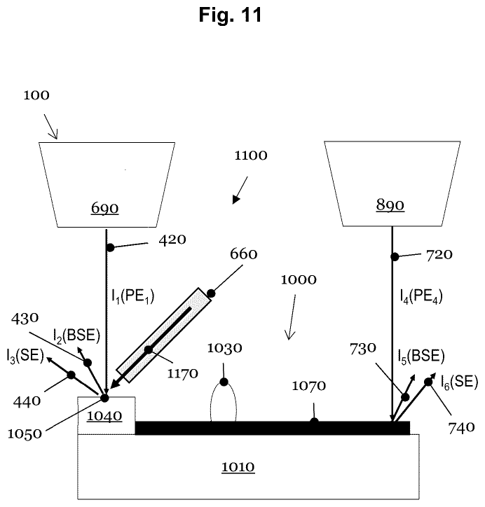

For the scanning of the electron beam 120 over the defect 150 in the mask 100 during repair thereof, it is advantageous to select the landing energy of the electrons 125 on the defect 150 to be as low as possible in order to make the diameter of the local chemical reaction induced by the electron beam 120 as small as possible. For this purpose, electron landing energies of 600 eV, preferably 400 eV and most preferably 300 eV or less are advantageous. For the imaging of the drift markers 160, it may be advantageous to use electron landing energies that are also used to repair a defect, that is to say electron landing energies in the range of 600 eV, preferably 400 eV and most preferably 300 eV or less. In addition, it may also be advantageous to carry out the imaging of drift markers (cf. FIG. 11 below) with electrons 125 of the electron beam 120 having landing energies in the range greater than 600 eV, for instance 3 keV.

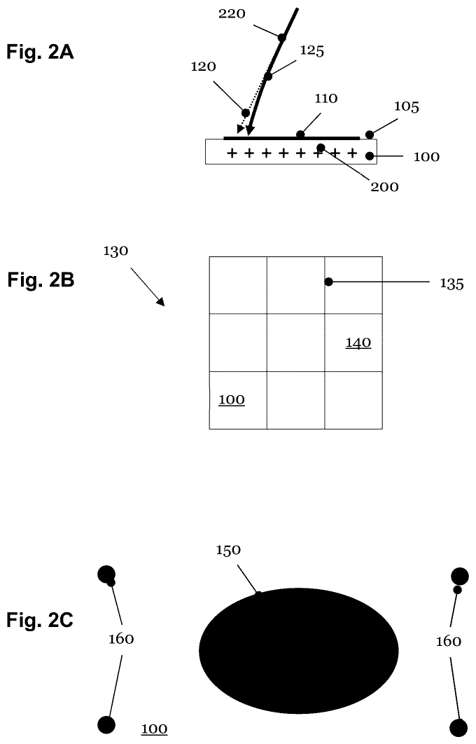

FIGS. 2A-2C once again repeat the illustrations of FIGS. 1A-1C. In contrast to FIGS. 1A-1C, the mask 100 in FIGS. 2A-2C however has a positive electrostatic charge 200. The electric field of the positive electrostatic charge 200 bends the electron beam 220 towards the surface 105 of the mask 100. For comparison, FIG. 2A additionally uses dashes to illustrate the electron beam 120 that would be incident on the surface 105 of the mask 100 if it were not electrostatically charged. FIG. 2B presents the reference structure 130 as is imaged by the electron beam 220 due to the positive electrostatic sample charge 200 of the mask 100. In comparison to the reference structure 130 in FIG. 1B, the reference structure 130 of the positively electrostatically charged mask 100 appears smaller. FIG. 2C shows the imaging of the defect 150 and of the four drift markers 160, which the electron beam 220 acquires due to the positive electrostatic mask charge 200 of these structural elements. The distance between the drift markers 160 in FIG. 2C appears to be reduced compared to that in FIG. 1B.

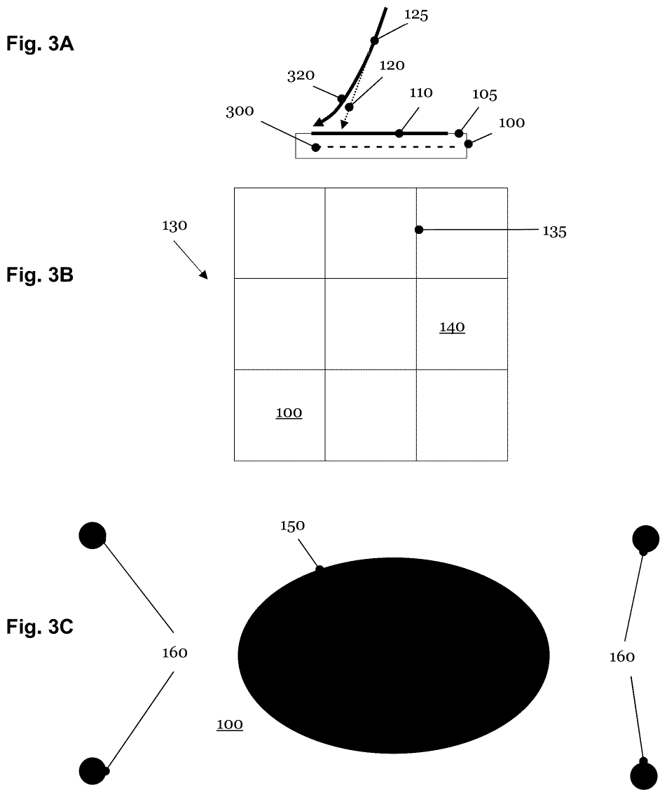

FIGS. 3A-3C show FIGS. 2A-2C, wherein the mask 100 now however has a negative electrostatic charge 300 instead of a positive electrostatic charge 200. The electric field of the negative sample charge 300 bends the path of the electrons 125 of the electron beam 320 away from the surface 105 of the mask 100. For comparison, the trajectory of the electron beam 120 incident on a non-electrostatically charged mask 100 is once again illustrated in dashed form. As illustrated in FIG. 3B, the deflection of the electron beam 320 caused by the negative electrostatic charge 300 increases the imaging of the reference structure 130 compared to the image thereof in FIG. 1B. The same applies to the imaging of the defect 150 and of the four drift markers 160 in FIG. 3C, again with reference to FIG. 1C.

It is possible to ascertain both the size, that is to say the numerical value, and the mathematical sign of the electrostatic charge 200, 300 of the mask 100 from the change in size of the reference structure 130, caused by an electrostatic charge 200, 300 of the mask 100 or, generally, of a sample 100. As illustrated by FIGS. 3A, 3B and 3C, an electrostatic sample charge 200, 300 may also be ascertained from measured displacements of the drift markers 160 with respect to the reference positions thereof. This in turn applies to the absolute value and the mathematical sign of an electrostatic sample charge 200, 300.

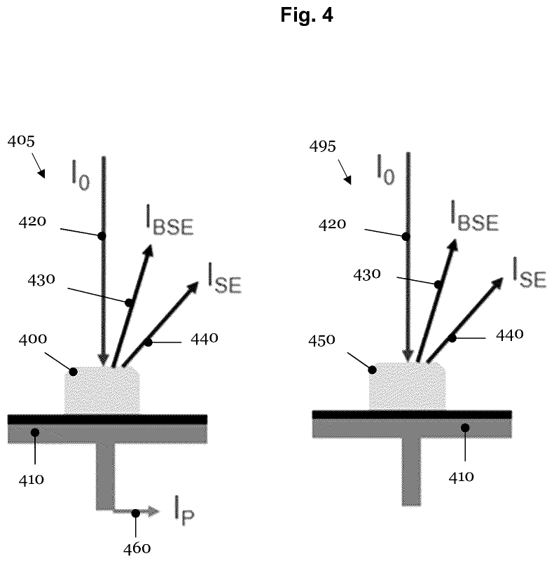

FIG. 4 shows an electrically conductive sample 400 in the left-hand partial image and an electrically insulating sample 450 in the right-hand partial image. The samples 400, 450 are arranged on an electrically conductive sample holder 410 (stage). FIG. 4 also schematically illustrates the currents that result when the samples 400, 450 are irradiated with an electron beam 420 with a current strength I₀. Some of the electrons 125 of the primary beam 420 that are incident on the sample 400, 450 are backscattered by the sample 400, 450, in a manner largely independent of the electrical conductivity of the sample 400, 450. The electrons (BSE) 430 backscattered by the sample 400, 450 form the current I_{BSE} directed away from the sample 400, 450. The current I_{BSE} is proportional to the current strength of the primary electron current I₀ incident on the sample 400, 450, that is to say I_{BSE}=η·I₀, wherein the proportionality constant η is referred to as yield coefficient.

Furthermore, there is typically a linear relationship between the incident current I₀ and the current I_{SE} generated by the SE 440 leaving the sample 400, 450: I_{SE}=δI₀, with the proportionality constant δ. In the case of the electrically conductive sample 400, an additional current Iₚ 460 may supply electric charges to the sample 400 or dissipate electric charges via the grounded sample holder 410. For reasons of charge maintenance, the following therefore applies for the conductive sample 400: I₀=I_{BSE}+I_{SE}+Iₚ. Or rewritten: Iₚ=I₀−I_{BSE}−I_{SE}=I₀(1−η−δ). This means that the current Iₚ compensates for excess or missing electric charges of the sample 400, thereby preventing electrostatic charging thereof.

The non-conductive sample 450 in the right-hand partial image of FIG. 4 prevents the flow of a compensation current Iₚ between the sample holder 410 and the sample 450, that is to say: Iₚ=0. This also applies for an electrically conductive sample 400 that is however not grounded, for example by virtue of the resting surface of the sample holder 410 being made of an electrically insulating material. This reduces the equation given above for charge maintenance: Iₚ=0=I₀−I_{BSE}−I_{SE}=I₀(1−η−δ). The sample 450 is not electrostatically charged only if the current strength, incident on the sample 450, of the primary electron beam 420 precisely compensates for the current strengths of the SE 440 I_{SE} and of the BSE 430 I_{BSE} in terms of absolute value. Otherwise, an equilibrium value Q(t→∞) is established for t→∞ (depending on the current strength I₀ and the sample size or the electrical conductivity thereof, times in the range of seconds or minutes are typically sufficient for this) for the accumulated charge. Samples 450 in the form of electrical insulators accumulate the electrostatic charge locally. On the other hand, non-grounded, electrically conductive samples 400 distribute the charge Q(t) evenly over the sample 400.

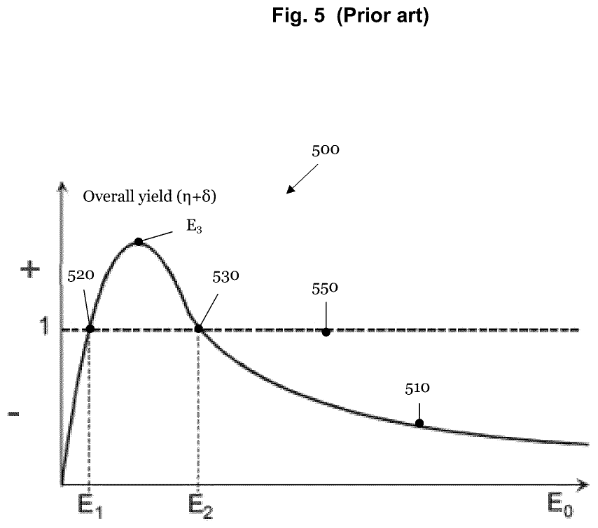

As illustrated in FIG. 5, the yield coefficients η and δ of the BSE and of the SE are a function of the landing energy E₀ of the primary electron beam 420. The graph 500 shows the profile 510 of the sum of the yield coefficients η and δ as a function of the landing energy E₀ of the primary electron beam 420 and is taken from the textbook “Physical Principles of Electron Microscopy,” F. R. Egerton, Springer 2005. Electron beams 420 having very small landing energies produce only very few SE and BSE. The number thereof cannot compensate for the charge introduced into the sample 450 by the electrons 125 of the primary beam 420, and the sample 450 is therefore negatively electrostatically charged 200. As landing energy E₀ increases, the number of SE 440 and BSE 430 generated per incident electron 125 increases, that is to say their yield coefficients η and δ rise sharply. If the landing energy E₀ reaches the first threshold value E₁ 520, an electron 125 incident on the sample 450 generates on average a total of one SE or one BSE. At the landing energy E₀=E₁, the charges introduced into the sample 450 by the electrons 125 and the charges dissipated from the sample 450 by the SE 440 and BSE 430 balance one another out precisely, and so the sample 450 is not electrostatically charged at the landing energy E₁ 520. The state I₀=I_{SE}+I_{BSE} is symbolized by the dashed line 550 in FIG. 5.

In the event of a further increase in the electron landing energy E₀, the yield coefficients η and δ continue to increase in order to reach their maximum value at the landing energy E₃. If the landing energy E₀ is increased beyond the value E₃, although the number of electrons that are able to detach the electrons 125 of the primary beam 420 from their bonds increases further, these electrons are increasingly released in deeper layers of the sample 450 and cannot reach the sample surface 105. As a result, the yield coefficients η and δ decrease, as does therefore the number of SE 440 and BSE 430 that are able to leave the sample 400, 450.

At the landing energy E₀=E₂, the charges introduced into the sample 450 by the electrons 125 and the charges that the SE 440 and BSE 430 dissipate from the sample 450 as I_{SE} and I_{BSE} balance out again. At the landing energy E₂ 530 of the electrons 125 of the primary beam 420, there is likewise no electrostatic charge 200, 300 of the sample 450. If the landing energy E₀ of the electrons is within the energy range E₁ to E₂, the sample 450 is positively electrostatically charged 200, while outside this energy range, that is to say E₀<E₁ and E₀>E₂, the sample 450 acquires a negative electrostatic charge 300.

Most known materials have an energy interval E₁<E₂ within which the landing energies of the electrons 125 lead to a positive net charge 200 of the material. For landing energies of the electrons 125 outside this energy range, on the other hand, the material is negatively electrostatically charged 300. The abovementioned textbook (R. F. Egerton: “Physical Principles of Electron Microscopy,” Springer 2005) indicates landing energies of the electrons 125 in the range of a few hundred electron volts (eV) for the lower energy threshold E₁ and numerical values in the range of around 1 keV to 10 keV for the upper energy threshold E₂.

As already mentioned above, the landing energies E₀ of the electrons 125 for imaging and processing lithographic masks 100 are usually at different values. One advantage of the methods described herein is that the landing energy E₀ of the electrons 125 may be optimized for their respective function, without the precision of the respective processing process being impaired by an electrostatic sample charge 200, 300.

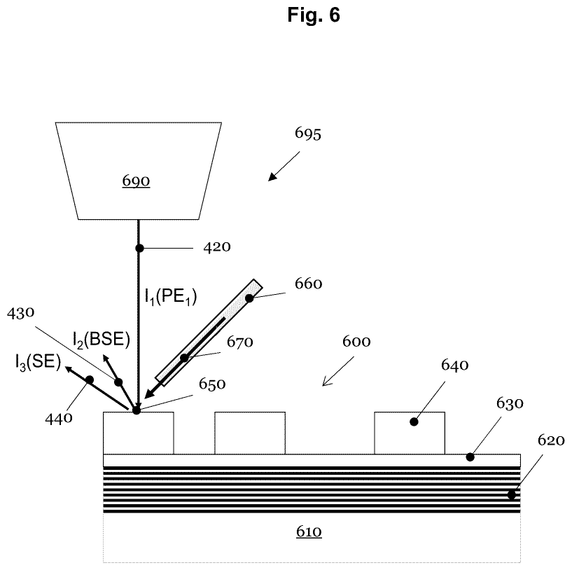

The diagram 695 in FIG. 6 illustrates the processing of an EUV mask 600 by carrying out a local chemical reaction on an absorbent pattern element 640. The EUV mask 600 has an electrically insulating substrate 610, for example a quartz substrate. On the substrate 610 is deposited a Bragg mirror 620 in the form of a multi-layer structure 620 having for example alternating silicon and molybdenum layers. An electrically conductive capping layer 630, for instance in the form of ruthenium (Ru), chromium (Cr) or chromium nitride (CrN), is deposited on the Bragg mirror 620. The capping layer 630 carries the absorbent electrically conductive pattern elements 640. These may comprise for example tantalum (Ta), tantalum nitride (TaN) or tantalum boron nitride (TaBN).

The active part of the EUV mask 600 is electrically conductive in the lateral directions through metal layers, but, in the vertical direction, its non-conductive substrate 610 electrically insulates the EUV mask 600 from the sample holder 410. In addition, the conductive capping layer 630 and the electrically conductive layers of the Bragg mirror 620 are typically interrupted by what are known as black borders. This results in larger conductive regions of the EUV mask 600 that are separated or isolated from one another in the lateral directions by black borders and in the vertical direction by the insulating substrate 610.

The defect 650 in the pattern element 640 may—similarly to the defect 150—be an excess-absorbent-material defect or a missing-absorbent-material defect. A gas provision system 660 provides, at the location of the defect 650, that is to say at the processing site, a precursor gas 670 in the form of a deposition gas (for an excess-material defect) or an etching gas (for a missing-material defect). In addition, an additive gas may be added to the precursor gas 670. The electron beam 420 having the current strength I₁ (PE₁) splits the precursor gas 670 adsorbed at the processing site and induces a local chemical etching or deposition reaction. The landing energy E₀ of the electrons 125 of the primary electron beam (PE) is selected to be as small as possible (in the range of a few hundred electron volts or less) in order to minimize the lateral dimensions of the local chemical reaction. In the range of these landing energies E₀, the currents, caused by the primary electron beam, of the SE 440 I₂(SE) and of the BSE 430 I₃(BSE) are small. These currents cannot compensate for the charge introduced into the EUV mask 600 by the primary beam 420, and the EUV mask 600 accumulates a negative electrostatic charge 300.

The electron beam 420 may also be used to image the EUV mask 600, in particular its defect 650. The defect 650 in the EUV mask 600 may be analyzed before it is processed. Furthermore, after the defect repair is complete, the processing site may be scanned again with the electron beam 420 in order to check the success of the repair process. During these process steps, the gas provision system 660 does not provide a precursor gas. In order to analyze the sample, that is to say the EUV mask 600 or its defect 650, the landing energy E₀ of the electrons 125 of the electron beam 420 may be increased in order to optimize the lateral resolution of the primary beam 420 or to ascertain a depth profile of the sample. The change in the landing energy E₀ changes the extent of the electrostatic charge of the EUV mask 600. Depending on the material of the absorbent pattern elements 640 and the landing energy E₀ of the electrons 125 of the primary beam 420, the mathematical sign of electrostatic charge 200, 300 may change.

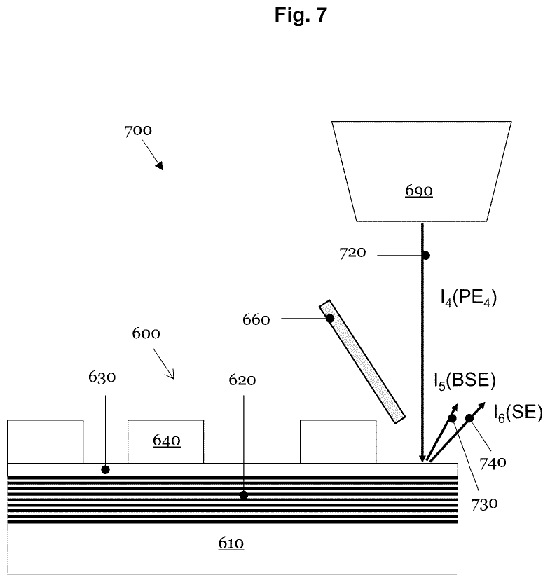

The diagram 700 in FIG. 7 presents the setting or the discharging of the electrostatic charge 200, 300 of the EUV mask 600 that it has experienced due to the repair, illustrated in FIG. 6, of the defect 650 and/or the analysis thereof. In order to set or to remove the electrostatic charge 200, 300, either the EUV mask 600 or the electron beam source 690 is moved, in a first step, to a site of the mask at which the electron irradiation carried out for discharging purposes is not able to exert any subsequent effect on the function of the EUV mask 600. The landing energy E₀ of the electrons of the electron beam 720 is then adjusted to a value that generates an electrostatic charge 200, 300 with a mathematical sign that is opposite to the electrostatic charge 200, 300 caused by the analysis process or the processing process. The irradiation of the capping layer 630 of the EUV mask 600 with the primary electron beam PE₄ 720 with the landing energy E₀ and the current strength I₄(PE₄) generates SE 740 with a current strength I₆(SE₆) and BSE 730 with a current strength I₅(SE₅). The difference between the currents I₄(PE₄), on the one hand, and I₅(BSE₅) and I₆(SE₆), on the other hand, introduces an amount of charge Q(t) into the capping layer 630 of the EUV mask 600 that reduces or compensates for the electrostatic charge 200, 300 of the EUV mask 600 caused by the processing of the defect 650. The time required to discharge the electrostatic charge 200, 300 depends, on the one hand, on the charge Q(t→∞) stored on the EUV mask 600 and the amount of charge q(t)=I₄(PE₄)−I₅(BSE₅)−I₆(SE₆) generated per unit of time.

The process for setting a defined electrostatic charge 200, 300, explained with reference to FIG. 7, may be carried out prior to carrying out an analysis process, for example in order to determine the position and the size of the defect 650 in the EUV mask 600. This makes it possible to ascertain the position and the size of the defect 650 with the greatest possible precision, thus creating the precondition for the best possible defect repair. The electrostatic charge 200, 300, generated by the analysis process, of the EUV mask 600 may be set to a desired extent, for instance the charge Q=0, prior to carrying out the defect repair. Before imaging the processing site of the EUV mask 600 in order to ascertain any remaining defect residual, the electrostatic charge 200, 300 may be set again to a predefined level.

The electron beam 720 may be focused on the capping layer 630 of the EUV mask 600. However, it is also possible, in particular if the EUV mask 600 allows, to direct the primary electron beam 720 onto the EUV mask 600 in expanded form in order to prevent any damage to the EUV mask 600 caused by the irradiation thereof. When using an expanded electron beam 720, care should be taken that this does not radiate beyond a black border of the mask 600. In this case, only some of the electrons would be available for setting the electrostatic charge 200, 300. The rest would, in an undesirable manner, electrostatically charge a region of the EUV mask 600.

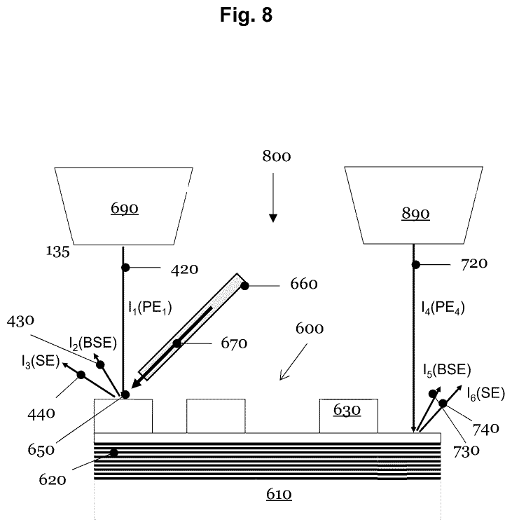

FIG. 8 presents the simultaneous analysis or processing of the EUV mask 600 and the setting of the electrostatic charge 200, 300 thereof. FIG. 8 thus combines the contents of FIGS. 6 and 7. Proceeding from FIG. 6, the first electron source 690, which generates the at least one other particle beam or electron beam in the example of FIG. 8, irradiates the defect 650 in the EUV mask 600 with electrons 125 of the primary electron beam 420 and a current strength I₁(PE₁). The landing energy E₀ of the electrons 125 is optimized with regard to carrying out the analysis process or the processing process of the defect 650 in the EUV mask 600. There is no need to take into consideration any impairment of the process execution that could possibly result. A second electron beam source 890, more generally a second particle beam source 890, generates the at least one particle beam, which irradiates the capping layer 630 of the EUV mask as an electron beam 720 the electrons 125 of which are adjusted or tuned to a landing energy E₀, such that the difference between the currents I₄(PE₄)−I₅(BSE₅)−I₆(SE₆) of the second electron source 890 precisely compensates for the difference between the currents I₁(PE₁)−I₂(BSE₂)−I₃(SE₃) of the first electron beam source 690. An electrostatic charge 200, 300 may thus be prevented, or the potential of the electrostatic charge 200, 300 of the mask 600 may be set to a desired level.

Upon the transition from a processing process of the EUV mask 600 to the analysis thereof with the accompanying change in the landing energy E₀ of the electrons 125 of the electron beam 420 (and the deactivation of the gas provision system 660), the landing energy E₀ of the electrons 125 of the electron beam 720 of the second electron source 890 may be adapted to the changed landing energy E₀ of the electrons 125 of the electron beam 420.

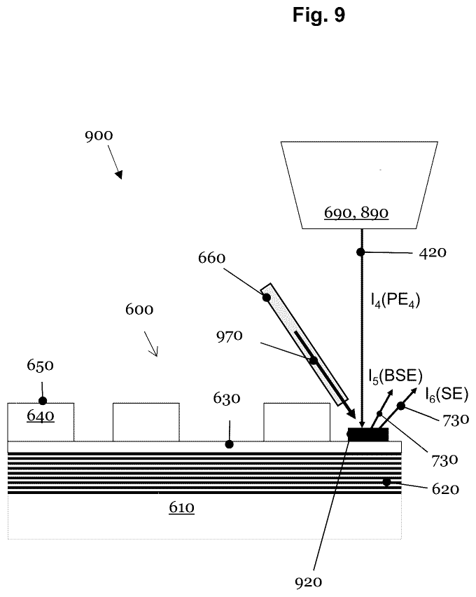

FIG. 9 illustrates one advantageous modification of the setting, discussed in FIGS. 7 and 8, of an electrostatic charge 200, 300 of the EUV mask 600. FIG. 9 once again repeats the setting, illustrated in FIG. 7, of the electrostatic charge 200, 300 of the EUV mask 600 from FIG. 7, with the difference that the primary electron beam 720 does not radiate onto the electrically conductive capping layer 630 of the EUV mask 600, but rather onto an electrically conductive sacrificial layer 920. The electrically conductive sacrificial layer 920 is deposited onto the capping layer 630 of the EUV mask 600. For this purpose, the gas provision system 660 provides a precursor gas 970 at the site at which the sacrificial layer 920 is to be deposited. The precursor gas 970 may comprise a metal carbonyl, in particular molybdenum hexacarbonyl (Mo(CO)₆). Furthermore, the precursor gas 970 may contain one or more additive gases. The at least one additive gas may comprise an oxidizing agent, for example nitrogen dioxide (NO₂).

The electrically conductive sacrificial layer 920 protects the capping layer 630 of the EUV mask 600 from possible damage caused by irradiation with the electron beam 720. This thus acts as a protective layer. The sacrificial layer 920 thus makes it possible to use more massive particles, such as ions, to set the electrostatic charge of the EUV mask 600, without the ions of the particle beam 720 being able to damage the EUV mask 600. The sacrificial layer 920 may be deposited on the capping layer 630 of the EUV mask 600 at a site that is not critical for it to function, on the one hand, and, on the other hand, is at such a large distance from the processing site of the defect 650 that it is possible to use a first radiation source 690 with a first particle beam 420 to process the defect 650, while at the same time a second radiation source 890 with a second particle beam 720 radiates onto the sacrificial layer 920 in order to set the electrostatic charge 200, 300 of the EUV mask 600. By way of example, the first radiation source 690 may direct electrons 125 onto the defect 650, and the second radiation source 890 may radiate ions onto the sacrificial layer 920 of the EUV mask 600.

The sacrificial layer 920 may be removed from the EUV mask 600 after the processing is complete using a mask cleaning process.

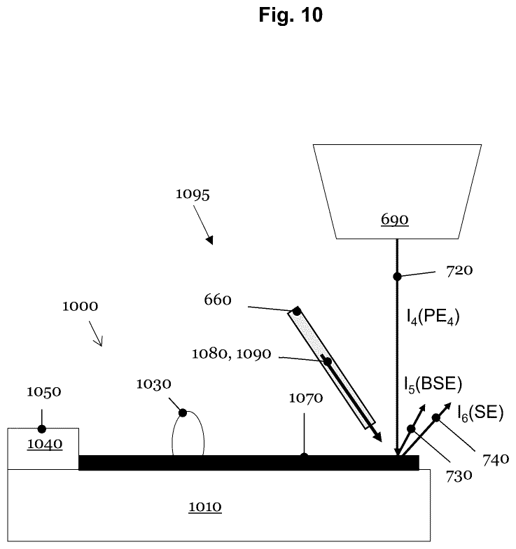

The diagram 1095 in FIG. 10 illustrates the setting of an electrostatic charge 200, 300 of a transmissive photomask 1000. It has an electrically non-conductive quartz substrate 1010. Absorbent electrically conductive pattern elements 1040 are arranged on the substrate 1010. These pattern elements may comprise for example chromium or a molybdenum silicide. The pattern element 1040 reproduced in the diagram 1095 has a defect 1050. The defect 1050 may be a dark defect, that is to say an excess-absorber-material defect, or a clear defect, that is to say a missing-absorber-material defect. An electrically conductive sacrificial layer 1070 or a protective layer 1070 is deposited on the substrate 1010 of the transmissive mask 1000 and extends to the defective pattern element 1040. The electrically conductive sacrificial layer 1070 may be deposited on the substrate 1010 by way of a particle beam-induced deposition process by providing a precursor gas 1080, which is adsorbed on the substrate 1010 of the mask 1000, and a particle beam 720, for instance an electron beam 720. By way of example, the precursor gas 1080 may comprise a metal carbonyl, such as chromium hexacarbonyl (Cr(CO)₆) or molybdenum hexacarbonyl (Mo(CO)₆) and an additive gas. The additive gas may comprise an oxidizing agent, for example oxygen (O₂), water (H₂O) or nitrogen dioxide (NO₂).

A drift marker 1030 is deposited on the sacrificial layer 1070 in the example of FIG. 10. The drift marker 1030 may likewise be deposited on the sacrificial layer 1070 by way of a particle beam-induced deposition process. The particle beam 720 from the radiation source 690 may be used for this purpose. A metal carbonyl, if necessary in combination with an additive gas, such as oxygen (O₂), a halogen-containing gas or nitrogen dioxide (NO₂), may again preferably be used as precursor gas 1090. By way of example, chromium hexacarbonyl (Cr(CO)₆) or molybdenum hexacarbonyl (Mo(CO)₆) may again be used as metal carbonyl. It is preferable here to use a different precursor gas 1090 for depositing the drift marker 1030 than for depositing the sacrificial or protective layer 1070. When imaging the drift marker 1030 with an electron beam 720, the reference element 1030, in addition to a topography contrast, is additionally delineated from the sacrificial layer 1070 by a material contrast.

In the schematic section illustrated in FIG. 10, a drift marker 1030 is deposited on the sacrificial layer 1070. Preferably, at least three drift markers 1030 are deposited on the sacrificial layer 1070 around the defect 1050. These drift markers 1030 span a 2D coordinate system in the plane of the mask 1000. The drift markers 1030 are scanned with the electron beam 720 before the defect 1050 is processed in order to ascertain their reference positions. From the reference positions of the drift markers 1030, it is additionally possible to ascertain whether the mask 1000 has an electrostatic charge 200, 300. This requires a calibration measurement in which the positions of the drift markers 1030 are ascertained as a function of the electrostatic charge of the mask 1000.

During the defect repair, the processing of the defect 1050 is interrupted periodically. The electron beam 720 is switched over from the processing mode with a first landing energy Eₒ(B) to the analysis mode with a second landing energy Eₒ(A), and the drift markers 1030 are scanned in the analysis mode. As explained above, it may be advantageous to select Eₒ(B)<Eₒ(A). It is possible to determine a relative displacement between the drift markers 1030 and the electron beam 720 from the acquired measurement data. In addition, it is possible to ascertain the extent and the mathematical sign of an electrostatic charge 200, 300 of the mask 1000 from the displacements of the drift markers 1030 based on their reference positions.

After the protective or sacrificial layer 1070 and the drift markers 1030 have been produced, the electron beam 720, after it has been adjusted accordingly, that is to say after the landing energy E₀ has been tuned, may irradiate the sacrificial layer 1070 in order to set an electrostatic potential before carrying out a first part of the repair of the defect 1050. After interrupting the defect repair and before scanning the drift markers 1030, the electron beam 720 may be adjusted in order to set the electrostatic charge 200, 300 of the mask 1000 to a desired level. The electron beam 720 is then switched to the analysis mode, and the drift markers 1030 are scanned. From these scan data, a drift between the defect 1050 and the electron beam 720 is determined and corrected. In addition, the electrostatic charge 200, 300 of the mask 1000 is ascertained from the scan data. If necessary, the electrostatic charge 200, 300 is set or reduced to a predefined potential before the processing process is continued.

These process steps are repeated until a defect residual that is still present no longer interferes with the imaging behavior of the mask 1000 in an impermissible manner, that is to say no longer generates a printable defect. After the process of repairing the defect 1050 is complete, the sacrificial layer 1070 together with the drift markers 1030 located thereon is removed from the mask 1000, preferably in a mask cleaning process.

In the same way as FIG. 8, FIG. 11 illustrates the simultaneous analysis or processing of the transmissive mask 1000 and the setting of its electrostatic charge 200, 300 with two radiation sources 690 and 890, which generate the at least one and the at least one other particle beam. The first radiation source 690 delivers for example an electron beam 420 with the current strength I₁(PE1₁), which irradiates the mask 1000 in order to analyze the defect 1050, and the BSE 430 and SE 430 generate currents I₂(BSE₂) and I₃(SE₃) that leave the mask 1000. The landing energy E₀ of the primary electron beam 420 is adapted to carrying out the defect analysis. The second radiation source 890, which radiates onto the electrically conductive sacrificial layer 1070 in the example of FIG. 11, provides an electron beam 720 the landing energy E₀ and current strength I₄(PE₄) of which are adjusted such that the electric charge generated thereby in the sacrificial layer 1070 per unit of time precisely balances out the charge generated by the electron beam 420 in the pattern element 1040. It is thereby possible to prevent an electrostatic charge 200, 300 of the mask 1000 during the analysis process, or to keep this at a predefined level.

Before carrying out the repair of the defect 1050, the landing energy E₀ of the electrons 125 of the electron beam 420 is optimized for the repair process. The gas provision system 660 is additionally activated in order to provide the precursor gas 1170 at the defect location. In addition, the landing energy E₀ of the electron beam 720 from the radiation source 890 is adapted to the changed landing energy of the electron beam 420, such that the two electron beams generate an equal amount of charge per unit of time in the pattern element 1040 and in the sacrificial layer 1070, respectively, but with an opposing mathematical sign. Electrostatic charging of the sample 1000 may thereby be reliably avoided even during sample processing.

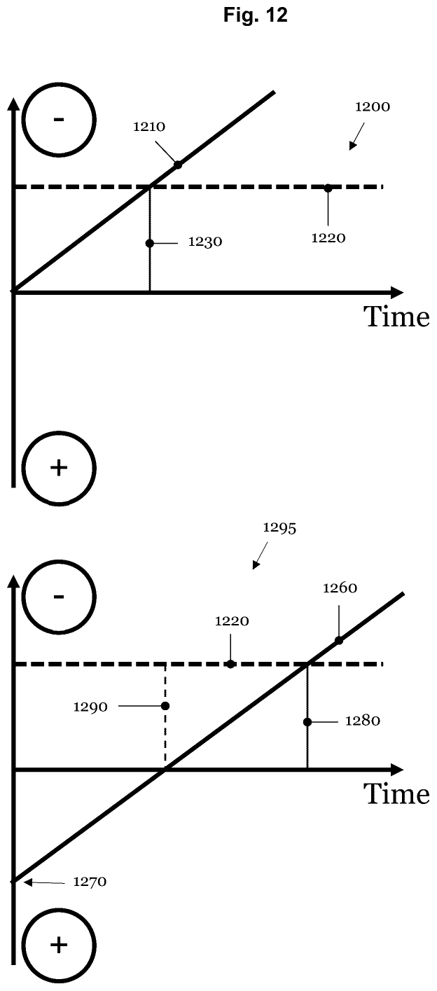

FIG. 12 illustrates a further embodiment of the method described herein for setting an electrostatic charge 200, 300 of a sample 100, 600, 1000. The sample 100, 600, 1000 is either an electrical insulator that accumulates charges locally when irradiated locally with a particle beam 120, 420, 720, or an electrical conductor that is not grounded. In the electrical conductor, the free electrons generated locally by irradiation are distributed over the entire sample 100, 600, 1000. The sample 100, 600, 1000 under consideration may furthermore have larger electrically conductive regions that are however isolated from one another.

The upper partial image 1200 shows the temporal profile of the electrostatic charge 1210 of a sample 100, 600, 1000 that is not charged at the start of the process. In the example illustrated in FIG. 12, charges are generated in the sample 100, 600, 1000 at a constant rate over time (q(t)=c), similarly to a capacitor charged with a current that is constant over time. Other temporal profiles of the electrostatic charge are of course possible. In the example illustrated in FIG. 12, the sample 100, 600, 1000 is negatively charged. It is thus irradiated by electrons with landing energies E₀ outside the energy interval E₁ to E₂ from FIG. 5.

The horizontal dashed line indicates a critical charge or a critical potential level 1220. In the case of electrostatic charges that are less than the critical potential level 1220 in terms of absolute value, electric fields are generated by the sample 100, 600, 1000 and disturb a charged particle beam 120, 420, 720 only to a tolerable extent. On the other hand, above the line of the critical potential level 1220, the electric field caused by the electrostatic charge 1210 deflects charged particles 125 from their desired trajectory such that the analysis and/or processing is impaired to an extent that is no longer acceptable. This applies equally for positive electrostatic charges that are greater (in terms of absolute value) than the positive electrostatic charge 1270 (cf. lower partial image 1295 in FIG. 12). In the upper partial image 1200, a sample 100, 600, 1000 may be irradiated with the particle beam 120, 420, 720 without infringing the specification in the time interval starting from zero until the time 1230.

The lower partial image 1295 in FIG. 12 presents the temporal profile of the electrostatic sample 100, 600, 1000 in the upper partial image 1200, wherein the sample, at the start of the irradiation process, has a positive electrostatic charge 1270 that reaches the critical threshold 1220 in terms of absolute value. The positive sample charge 1270 may be achieved for example by irradiation with electrons 125 the charge energy E₀ of which is in the energy interval E₁ to E₂ (FIG. 5), in which an irradiated sample 100, 600, 1000 is charged positively. As a result of the positive precharge 1270 of the sample 100, 600, 1000, in the example illustrated in FIG. 12, the electrostatic charge 1260 is shifted by a time interval of zero to the time 1290 compared to the partial image 1200. This makes it possible to double the time 1280 for which it is possible to carry out analysis or processing by irradiation with a charged particle beam 120, 420, 720 without infringing specifications.

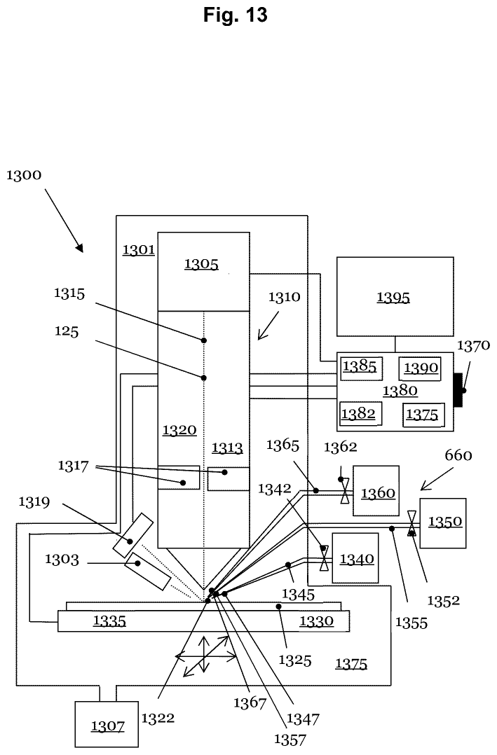

FIG. 13 shows a schematic section through a few important components of a device 1300 that may be used to set an electrostatic charge 200, 300 of a sample 100, 600, 1000, in particular of a lithographic mask 100, 600, 1000. The exemplary device 1300 in FIG. 13 comprises a modified scanning particle microscope 1310 in the form of a scanning electron microscope (SEM) 1310 in combination with a gas provision system 660.

The device 1300 has a particle beam source 1305 in the form of an electron beam source 1305 that generates an electron beam 1315 as particle beam 1315. An electron beam 1315 has the advantage—compared to an ion beam—that the electrons 125 incident on the sample 1325 or the lithographic mask 100, 600, 1000 substantially cannot damage the sample or the mask 100, 600, 1000. However, it is also possible to use an ion beam, an atomic beam, a molecular beam or a photon beam (not illustrated in FIG. 13) for the purpose of processing the sample 1325 in the device 1300.

The scanning particle microscope 1310 is composed of an electron beam source 1305 and a column 1320, in which is arranged the beam optical unit 1313 for instance in the form of an electron optical unit of the SEM 1310. In the SEM 1310 in FIG. 13, the electron beam source 1305 generates an electron beam 1315, which is directed as a focused electron beam 1315 onto the sample 1325, which may comprise the lithographic mask 100, 600, 1000, at the site 1322 by the imaging elements arranged in the column 1320, said imaging elements not being illustrated in FIG. 13. The beam optical unit 1313 thus forms the imaging system 1313 of the electron beam source 1305 of the SEM 1300. The electron beam 1315 of the electron beam source 1305 represents one possible embodiment of a particle beam or of another particle beam.

The imaging elements of the column 1320 of the SEM 1310 may furthermore scan the electron beam 1315 over the sample 1325. The sample 1325 may be examined, that is to say analyzed and processed, with the aid of the electron beam 1315 of the SEM 1310. A diaphragm or a diaphragm system comprising multiple diaphragms (not illustrated in FIG. 13) may be installed in the column 1320 of the SEM 1310, preferably downstream of a condenser lens of the SEM 1310. The diaphragm or the diaphragm system may be adjusted by a setting unit 1390 of the computer system 1380 of the device 1300.

The backscattered electrons (BSE) and secondary electrons (SE) generated by the electron beam 1315 in the region of interaction of the sample 1325 are registered by the detector 1317. The detector 1317 that is arranged in the electron column 1320 is referred to as “in lens detector.” The detector 1317 may be installed in the column 1320 in various embodiments. The detector 1317 converts the SE generated by the electron beam 1315 at the measurement point 1322 and/or the BSE backscattered by the sample 1325 into an electrical measurement signal and forwards the latter to an evaluation unit 1385 of a computer system 1380 of the device 1300. The detector 1317 may contain a filter or a filter system in order to discriminate the SE and BSE in terms of energy and/or solid angle (not reproduced in FIG. 13). The detector 1317 is controlled by a setting unit 1390 of the device 1300.

The exemplary device 1300 may include a second detector 1319. The second detector 1319 may be designed to detect electromagnetic radiation, in particular in the X-ray range. As a result, the detector 1319 makes it possible to analyze a material composition of the radiation generated by the sample 1325 during the examination thereof. The detector 1319 is likewise controlled by the setting unit 1390.

The device 1300 may furthermore comprise a third detector (not illustrated in FIG. 13). The third detector is often embodied in the form of an Everhart-Thornley detector and typically arranged outside the column 1320. It is generally used to detect SE.

The device 1300 comprises a flood gun 1303. This is able to provide ions with low kinetic energy in the region of the sample 1325. The flood gun 1303 may furthermore be configured to provide electrons with settable landing energy E₀ in that region of the sample 1325 to be processed and/or to be analyzed. The ions with low kinetic energy and/or the electrons 125 with settable landing energy E₀ are able to compensate for an electrostatic charge 200, 300 of the sample 1325. Furthermore, the ions or the electrons from the flood gun 1303 may be used to set an electrostatic sample charge 200, 300 to a predefined charge level. The flood gun 1303 thus illustrates one exemplary embodiment of a particle beam.

Instead of the flood gun 1303 or in addition to the flood gun 1303, the device 1300 may include a second particle beam source 890 that generates a second particle beam 720 (not reproduced in FIG. 13). The second particle beam source 890 may have the same imaging elements as or imaging elements similar to the first particle beam source 1305. In addition, the second particle beam source 890 may have one or more of the detectors 1317, 1319. This means that the device 1300 may include a second scanning particle microscope (not illustrated in FIG. 13).

The device 1300 may furthermore have a mesh at the output of the column 1320 of the modified SEM 1310 (not shown in FIG. 13). By applying a voltage between the mesh and a metal tube (liner tube) mounted in the region of the objective lens of the column 1320, which metal tube is likewise not shown in FIG. 13, it is possible to generate a settable braking voltage for the electrons 125 of the electron beam 1315, such that their landing energy E₀ is able to be adjusted to a desired value. In addition, the mesh may likewise be used to compensate for an electrostatic charge 200, 300 of a sample 1325. It is furthermore possible to ground the mesh.

In addition to the electron beam source 1305, the device 1300 may comprise a second radiation source 890 (not shown in FIG. 13). The second radiation source 890 may be a second electron beam source 890 or a radiation source for another particle type, for instance for ions, atoms, molecules or high-energy photons.

The sample 1325 is arranged on a sample stage 1330 or a sample holder 1330 for examination. A sample stage 1330 is also known as a “stage” in the specialist field. As symbolized by the arrows in FIG. 13, the sample stage 1330 may be moved in three spatial directions relative to the column 1320 of the SEM 1310, for example by way of micro-manipulators that are not illustrated in FIG. 13. In particular, the sample stage 1330 is able to move the sample 1325 from the at least one site 630, 920, 1070 at which an adjusted particle beam 720 radiates onto the sample 1325 to the at least one site 150, 650, 1050 or defect 150, 650, 1050 to be analyzed or to be processed.

In addition to the translational movement, the sample stage 1330 may be rotated at least about an axis that is oriented parallel to the beam direction of the particle beam source 1305. It is furthermore possible for the sample stage 1330 to be embodied such that it is rotatable about one or two further axes, this axis or these axes being arranged in the plane of the sample stage 1330. The two or three axes of rotation preferably form a rectangular coordinate system. As may be gathered from FIG. 13, the rotation of the sample stage 1330 about an axis of rotation that is arranged in the plane of the sample stage 1330 is often possible only to a limited extent on account of the small distance between the end of the column and the sample 1325.

The sample 1325 to be examined may be any microstructured component or component part requiring analysis and, possibly, subsequent processing, for example the repair of a local defect 150, 600, 1050 in a lithographic mask 150, 650, 1000. By way of example, the sample 1325 may thus comprise a transmissive photomask 1000 or a reflective photomask 600 and/or a template for nanoimprint technology. The transmissive photomask 1000 and the reflective photomask 600 may comprise all types of photomasks, such as binary masks, phase-shifting masks, OMOG masks, or masks for double or multiple exposure.

The device 1300 in FIG. 13 may furthermore comprise one or more scanning probe microscopes, for example in the form of an atomic force microscope (AFM) (not shown in FIG. 13), which may be used to analyze and/or process the sample 1325.

The scanning electron microscope 1310 illustrated by way of example in FIG. 13 is operated in a vacuum chamber 1301. In order to generate and maintain a reduced pressure required in the vacuum chamber 1301, the SEM 1310 in FIG. 13 has a pump system 1307.

The device 1300 includes a computer system 1380. Said computer system comprises a setting unit 1390 that is configured to set the landing energy E₀ of the electrons 125 of the electron beam 1315 to a predefined value. For this purpose, the evaluation unit 1385 is able to set the acceleration voltage of the electrons 125 of the electron beam 1315 along with the braking voltage thereof.

The computer system 1380 may furthermore have an interface 1370 via which the computer system 1380 receives information about the sample 1325, for instance its material composition and/or its surface contour. The computer system 1380 may additionally receive information about a defect 150, 650, 1050 in the sample 1325. The computer system 1380 may additionally comprise a user interface 1375 via which a user provides the landing energy E₀ of the electrons 125 of the electron beam 1315 to the computer system 1380. However, it is also possible for the user to provide the computer system 1380, via the user interface 1375, with only possible energy ranges for setting the landing energy E₀ of the electrons 125 of the electron beam 1315, and for the computer system 1380 to ascertain the landing energy E₀ of the electrons 125 of the electron beam 1315 and for the setting unit 1390 of the computer system 1380 to set the acceleration voltage and/or the braking voltage accordingly.

The computer system 1380 may also comprise a scanning unit 1382, which scans the electron beam 1315 over the sample 1325. The setting unit 1390 may furthermore be configured to set the various parameters of the modified scanning particle microscope 1310 of the device 1300. The setting unit 1390 may furthermore control the micromanipulators and rotation of the sample stage 1330. The computer system 1380 may additionally be configured to control the flood gun 1303 and/or a second radiation source 890 or to scan over the sample 1325.

Moreover, the evaluation unit 1385 of the computer system 1380 may analyze the measurement signals from the detectors 1317 and 1319 and generate therefrom an image of the sample 1325 that is able to be displayed by a display 1395. In particular, the evaluation unit 1385 may be designed to determine, from the measurement data from the detector 1317, the position and a contour of a missing-material defect 650, 1050 and/or an excess-material defect 150, 650, 1050 in a sample 1325, for instance the lithographic mask 100, 600, 1000.

The evaluation unit 1385 may additionally contain one or more algorithms that make it possible to ascertain the size and the mathematical sign of an electrostatic charge 200, 300 of the sample 1325 from an image of one or more reference structures 130. The evaluation unit 1385 may furthermore comprise one or more algorithms that are designed to ascertain the extent and the mathematical sign of an electrostatic sample charge 200, 300 from position shifts of three or more drift markers 1030. The evaluation unit 1385 furthermore includes one or more algorithms that are designed, from the determined electrostatic charge 200, 300, the material composition of the sample 1325 and its surface contour, to ascertain the landing energy E₀ of the particles 125 of the particle beam 1315 that is used to set or compensate for the electrostatic sample charge 200, 300. The algorithms of the evaluation unit 1385 may be implemented using hardware, software or a combination thereof. In particular, the one or more algorithms may be implemented in the form of an ASIC (application-specific integrated circuit) and/or an FPGA (field-programmable gate array).

The computer system 1380 and/or the evaluation unit 1385 may include a memory, preferably a non-volatile memory (not illustrated in FIG. 13), which stores a material database for samples 1325 and models of forms of repair for different mask types 100, 600, 1000. The evaluation unit 1385 may be designed to calculate a form of repair for the one or more defects 150, 650, 1050 in the lithographic mask 600, 1000 from the measurement data from the detector 1317 on the basis of a repair model. Furthermore, the computer system 1380 may comprise an interface 1370 for exchanging data with the Internet, an Intranet and/or some other device. The interface 1370 may comprise a wireless or wired interface. The evaluation unit 1385 may provide the setting unit 1390 with data that allow the setting unit 1390 to adjust the landing energy E₀ of the particles 125 of the particle beam 1315 automatically, that is to say without interaction of a user.

The evaluation unit 1385 and/or the setting unit 1390 may be integrated into the computer system 1380, as indicated in FIG. 13. However, it is also possible to embody the evaluation unit 1385 and/or the setting unit 1390 as stand-alone unit(s) within or outside the device 1300. In particular, the evaluation unit 1385 and/or the setting unit 1390 may be designed to carry out some of their tasks by way of a dedicated hardware implementation.

The computer system 1380 may furthermore be integrated into the device 1300, or may be designed as a stand-alone device (not shown in FIG. 13). The computer system 1380 may be embodied using hardware, software, firmware or a combination.

The gas provision system 660 implemented by the device 1300 is discussed below. As already explained above, the sample 1325 is arranged on a sample stage 1330. The imaging elements of the column 1320 of the SEM 1310 are able to focus the electron beam 1315 and scan it over the sample 1325. The electron beam 1315 of the SEM 1310 may be used to induce a particle beam-induced deposition process (EBID, electron beam-induced deposition) and/or a particle beam-induced etching process (EBIE, electron beam-induced etching). The exemplary device 1300 in FIG. 13 has three different supply containers 1340, 1350 and 1360, for storing various precursor gases, in order to carry out these processes.

The first supply container 1340 stores a precursor gas, for example a metal carbonyl, such as chromium hexacarbonyl (Cr(CO)₆) or molybdenum hexacarbonyl (Mo(CO)₆). With the aid of the precursor gas stored in the first supply container 1340, material missing from the lithographic mask 100, 600, 1000 may be deposited thereon in a local chemical deposition reaction, for example. Furthermore, a protective layer 1070 or a sacrificial layer 1070 may be deposited on the mask 600, 1000 by way of the precursor gas stored in the first storage container 1340. In addition, drift markers 1030 may be deposited on the mask 600, 1000 or the sacrificial layer 1070 by way of the precursor gas stored in the first storage container 1340.

The electron beam 1315 of the SEM 1310 acts as an energy supplier for splitting the precursor gas, which is stored in the first supply container 1340, at the site where material is intended to be deposited on the sample 1325. This means that the combined provision of an electron beam 1315 and a precursor gas leads to an EBID process being carried out for local deposition of missing material, for example material missing from the mask 600, 1000.

An electron beam 1315 may be focused on a spot diameter in the range of a few nanometers. The region of interaction or the scattering cone in which an electron beam 1315 generates SE depends firstly on the energy of the electron beam 1315 and secondly on the material composition on which the electron beam 1315 is incident. The diameters of regions of interaction attain values in the low single-digit nanometer range. The diameter of a scattering cone of an electron beam 1315 thus limits the achievable resolution limit when carrying out a local particle beam-induced reaction. This resolution limit at present is in the single-digit nanometer range.

In the device 1300 illustrated in FIG. 13, the second supply container 1350 stores an etching gas that allows a local electron beam-induced etching (EBIE) process to be carried out. With the aid of an electron beam-induced etching process, excess material is able to be removed from the sample 1325, for instance the excess material of the pattern element 640, 1040 is able to be removed from the mask 600, 1000. By way of example, an etching gas may comprise xenon difluoride (XeF₂), a halogen or nitrosyl chloride (NOCl).

An additive or additional gas may be stored in the third supply container 1360, said gas, where necessary, being able to be added to the etching gas kept available in the second supply container 1350 or to the precursor gas stored in the first supply container 1340. As an alternative, the third supply container 1360 may store a second precursor gas or a second etching gas.

In the device 1300 illustrated in FIG. 13, each of the supply containers 1340, 1350 and 1360 of the gas provision system 660 has its own control valve 1342, 1352 and 1362 in order to supervise or control the amount of the corresponding gas that is provided per unit of time, that is to say the gas volumetric flow at the site 1322 where the electron beam 1315 is incident on the sample 1325. The control valves 1342, 1352 and 1362 may be controlled or supervised by the setting unit 1390 of the computer system 1380. By this means, it is possible to set the partial pressure conditions of the gas or gases provided at the processing location for carrying out an EBID and/or EBIE process in a wide range.

Furthermore, in the exemplary device 1300 in FIG. 13, each supply container 1340, 1350 and 1360 has its own gas feedline system 1345, 1355 and 1365, which ends with a nozzle 1347, 1357 and 1367 in the vicinity of the point of incidence of the electron beam 1315 on the sample 1325.

The supply containers 1340, 1350 and 1360 may have their own temperature setting element and/or control element, which allows both cooling and heating of the corresponding supply containers 1340, 1350 and 1360. This makes it possible to store and in particular provide the precursor gas at the respectively optimum temperature (not shown in FIG. 13). The setting unit 1390 is able to control the temperature setting elements and the temperature control elements of the supply containers 1340, 1350, 1360. During the EBID and the EBIE processing processes, the temperature setting elements of the supply containers 1340, 1350 and 1360 may furthermore be used to set the vapor pressure of the precursor gases stored therein by way of the selection of an appropriate temperature.

The device 1300 may comprise more than one supply container 1340 in order to store two or more precursor gases. The device 1300 may furthermore comprise more than one supply container 1350 in order to store two or more etching gases (not shown in FIG. 13).

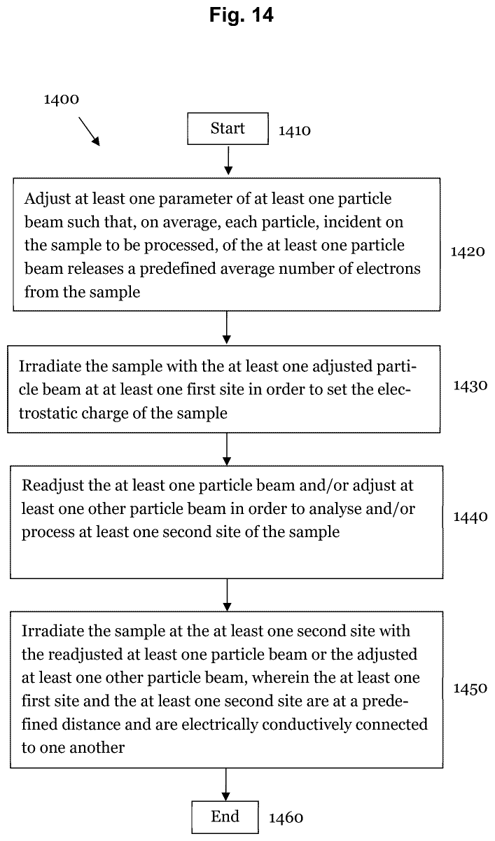

The flowchart 1400 in FIG. 14 furthermore represents essential steps of a method for setting an electrostatic charge 200, 300 of a sample 100, 600, 1000, 1325. The method begins in step 1410. In step 1420, at least one parameter of at least one particle beam 120, 420, 720, 1315 is adjusted such that, on average, each particle 125, incident on the sample 100, 600, 1000, 1325, of the at least one particle beam 120, 420, 720, 1325 releases a predefined average number of electrons from the sample 100, 600, 1000 to be repaired. The at least one parameter may be adjusted for example by setting a landing energy E₀ of the particles 125 of the at least one particle beam 120, 420, 720, 1325. For this purpose, the setting unit 1390 of the device 1300 is able to set or adjust the acceleration voltage and/or the braking voltage of the particles 125 of the at least one particle beam 120, 420, 720, 1325 accordingly.

In step 1430, the at least one adjusted particle beam 720 irradiates the sample 100, 600, 1000, 1325 at least one first site 620, 930, 1070 in order to set the electrostatic charge 200, 300 of the sample 100, 600, 1000, 1325.

In step 1440, the at least one particle beam 120, 420, 720, 1325 is readjusted and/or at least one other particle beam 120, 420, 1325 is adjusted in order to analyze and/or process at least one second site 150, 650, 1050 of the sample 100, 600, 1000, 1325. Next, in step 1450, the sample 100, 600, 1000, 1325 is irradiated at the at least one second site 150, 650, 1050 with the readjusted particle beam 720 or the adjusted other particle beam 420, wherein the at least one first site 620, 930, 1070 and the at least one second site 150, 650, 1050 are at a predefined distance and are electrically connected to one another.

The method ends in step 1460.

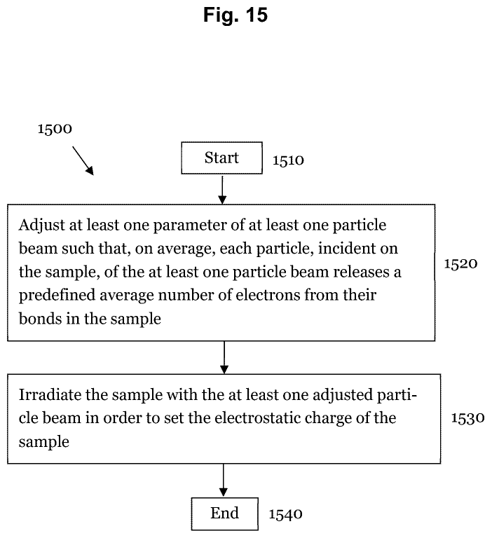

Finally, the flowchart 1500 in FIG. 15 represents essential steps of a further method for setting an electrostatic charge 200, 300 of a sample 100, 600, 1000, 1325. The method begins in step 1510. In step 1520, at least one parameter of at least one particle beam 120, 420, 720, 1325 is adjusted such that, on average, each particle 125, incident on the sample 100, 600, 1000, 1325, of the at least one particle beam 120, 420, 720, 1325 releases a predefined average number of electrons from the sample 100, 600, 1000, 1325. The at least one parameter may be adjusted for example by setting a landing energy E₀ of the particles 125 of the at least one particle beam 120, 420, 720, 1325. For this purpose, the setting unit 1390 of the device 1300 is able to set or adjust the acceleration voltage and/or the braking voltage of the particles 125 of the at least one particle beam 120, 420, 720, 1325 accordingly.

In step 1530, the sample 100, 600, 1000, 1325 is irradiated with the at least one adjusted particle beam 720 in order to set the electrostatic charge 200, 300 of the sample 100, 600, 1000, 1325. The method ends in step 1540.

What is claimed is:

1. A method for setting an electrostatic charge of a sample, comprising:
a. adjusting at least one parameter of at least one particle beam such that, on average, each particle, incident on the sample, of the at least one particle beam releases a predefined average number of electrons from the sample;
b. irradiating the sample with the at least one adjusted particle beam at at least one first site in order to set the electrostatic charge of the sample;
c. readjusting at least one parameter of the at least one particle beam and/or adjusting at least one other particle beam so as to enable analysis and/or processing of at least one second site of the sample; and
d. irradiating the at least one second site of the sample with the readjusted at least one particle beam and/or the adjusted at least one other particle beam, wherein the at least one first site and the at least one second site are at a predefined distance and are electrically conductively connected to one another.

2. The method of claim 1, wherein steps b. and d. are carried out simultaneously.

3. The method of claim 1, wherein steps b. and d. are carried out sequentially.

4. The method of claim 1, wherein the at least one particle beam irradiates the at least one first site with a first adjustment, irradiates the at least one second site with a second adjustment for processing purposes, and/or irradiates the at least one second site with a third adjustment for analysis purposes.

5. The method of claim 1, wherein the at least one particle beam irradiates the at least one first site with a first adjustment and the at least one other particle beam irradiates the at least one second site with a first adjustment in order to process them; or wherein the at least one particle beam irradiates the at least one first site with a second adjustment and the at least one other particle beam irradiates the at least one second site with a second adjustment in order to analyze them.

6. The method of claim 1, wherein the predefined distance is selected such that the irradiation of the at least one first site with the at least one particle beam at the predefined distance does not substantially affect the irradiation of the at least one second site with the at least one particle beam or the at least one other particle beam in order to analyze and/or process the at least one second site of the sample.

7. The method of claim 1, wherein the predefined distance between the at least one first site and the at least one second site comprises at least a length or a width of a scan region of the at least one particle beam and/or of the at least one other particle beam.

8. The method of claim 1, wherein the irradiation of the at least one second site, in order to irradiate the at least one second site, comprises: providing at least one precursor gas at the at least one second site.

9. The method of claim 1, wherein, at the at least one first site, a concentration of the at least one precursor gas is less than 50% of a maximum concentration at the at least one second site to be processed.

10. The method of claim 1, wherein the predefined distance between the at least one first site and the at least one second site is at least 20 μm.

11. The method of claim 1, furthermore comprising:
interrupting the irradiation of the at least one particle beam and/or of the at least one other particle beam for processing the at least one second site;
determining a position of at least one drift marker;
determining a deviation of the determined position of the at least one drift marker from a reference position;
correcting a position at which the at least one particle beam and/or the at least one other particle beam is incident on the at least one second site by the ascertained deviation; and
continuing the irradiation with the at least one particle beam and/or with the at least one other particle beam in order to process the at least one second site.

12. A method for setting an electrostatic charge of a sample, comprising:
a. adjusting at least one parameter of at least one particle beam such that, on average, each particle, incident on the sample, of the at least one particle beam releases a predefined average number of electrons from the sample;
b. irradiating the sample with the at least one adjusted particle beam in order to set the electrostatic charge of the sample; and
c. providing at least one precursor gas at a processing site of the sample (in order to repair at least one defect in the sample during the irradiation of the sample with the at least one adjusted particle beam.

13. The method of claim 1, wherein the adjustment of the at least one parameter of the at least one particle beam and/or of the at least one other particle beam comprises changing at least one parameter from the following group: a landing energy of the particles, incident on the sample, of the at least one particle beam and/or of the at least one other particle beam, a wavelength of the particles, incident on the sample, of the at least one particle beam and/or of the at least one other particle beam, a flux density of the particles, incident on the sample, of the at least one particle beam and/or of the at least one other particle beam, and an irradiation time of the particles, incident on the sample, of the at least one particle beam and/or of the at least one other particle beam.

14. The method of claim 1, wherein the adjustment of the at least one parameter furthermore comprises at least one of: determining a current strength and/or a flux density of the at least one particle beam or determining an irradiation time of the sample with the at least one particle beam and/or the at least one other particle beam.

15. The method of claim 12, wherein the at least one particle beam comprises at least one first particle beam and at least one second particle beam.

16. The method of claim 15, furthermore comprising: analyzing and/or processing the sample with the at least one second adjusted particle beam and setting the electrostatic charge of the sample by way of the at least one first adjusted particle beam.

17. The method of claim 15, furthermore comprising: simultaneously irradiating the sample with the at least one first particle beam with a first adjustment and the at least one second particle beam with a second adjustment.

18. The method of claim 12, furthermore comprising: electrically connecting a second site, to be analyzed and/or to be processed, of the sample to at least one first site of the sample, wherein the second site to be analyzed and/or to be processed and the at least one first site are at a predefined distance from one another.

19. The method of claim 12, wherein the sample comprises at least one defect around at least part of which an electrically conductive protective layer is placed, and wherein the at least one second adjusted particle beam irradiates the at least one defect and the at least one first adjusted particle beam irradiates the electrically conductive protective layer.

20. The method of claim 1, furthermore comprising the following step: determining the electrostatic charge of the sample by way of at least one element from: a change in size of at least one reference structure of the sample or a drift correction of the at least one adjusted particle beam during analysis and/or processing of the sample.

21. The method of claim 1, furthermore comprising the following step:
electrostatically charging the sample within a predefined potential interval by irradiation with the at least one particle beam with a first adjustment before processing and/or analyzing the sample with at least one second adjustment of the at least one particle beam, in particular at least one defect in the sample.

22. A computer program stored in a non-volatile memory and containing instructions that cause a computer system to carry out the method steps of claim 1.

23. A device for setting an electrostatic charge of a sample, having:
a. means for adjusting at least one parameter of at least one particle beam such that, on average, each particle, incident on the sample, of the at least one particle beam releases a predefined average number of electrons from the sample;
b. means for irradiating the sample with the at least one adjusted particle beam at at least one first site in order to set the electrostatic charge of the sample;
c. means for adjusting at least one other particle beam in order to analyze and/or process at least one second site of the sample; and
d. means for irradiating the at least one second site of the sample with the readjusted at least one particle beam and/or the adjusted at least one other particle beam, wherein the at least one first site and the at least one second site are at a predefined distance and are electrically conductively connected to one another.

24. A device for setting an electrostatic charge of a sample, having:
a. means for adjusting at least one parameter of at least one particle beam such that, on average, each particle, incident on the sample, of the at least one particle beam releases a predefined average number of electrons from the sample;
b. means for irradiating the sample with the at least one adjusted particle beam in order to set the electrostatic charge of the sample; and
c. means for providing at least one precursor gas at a processing site of the sample during the irradiation of the sample with the at least one adjusted particle beam in order to repair at least one defect in the sample.

25. The device of claim 23, wherein the device is configured to carry out a method for setting the electrostatic charge of the sample, the method comprising:
a. adjusting the at least one parameter of the at least one particle beam such that, on average, each particle, incident on the sample, of the at least one particle beam releases the predefined average number of electrons from the sample;
b. irradiating the sample with the at least one adjusted particle beam at the at least one first site in order to set the electrostatic charge of the sample;
c. readjusting at least one parameter of the at least one particle beam and/or adjusting the at least one other particle beam so as to enable the analysis and/or the processing of the at least one second site of the sample; and
d. irradiating the at least one second site of the sample with the readjusted at least one particle beam and/or the adjusted at least one other particle beam, wherein the at least one first site and the at least one second site are at the predefined distance and are electrically conductively connected to one another.

26. The device of claim 23, wherein the means for adjusting the at least one parameter of the at least one particle beam and/or of the at least one other particle beam comprises at least one element: means for setting an acceleration voltage of the particles of the at least one particle beam and/or of the at least one other particle beam, means for setting a braking voltage of the particles of the at least one particle beam and/or of the at least one other particle beam, means for setting a wavelength of the particles of the at least one particle beam and/or of the at least one other particle beam, means for setting a flux density of the at least one particle beam and/or of the at least one other particle beam, or means for setting an irradiation time of the particles of the at least one particle beam and/or of the at least one other particle beam.

27. The device of claim 23, furthermore having at least one element from: an electron flood gun, an ion flood gun, an adjustable diaphragm for the at least one particle beam, at least one second particle beam source for generating at least one second particle beam, or an energy-selective detector for secondary electrons and/or backscattered electrons.

28. The device of claim 23, furthermore having: means for displacing a point of incidence of the at least one particle beam from the at least one first site of the sample to the at least one second site of the sample.

29. The device of claim 23, furthermore having: means for carrying out a form of repair by way of the at least one other particle beam at the at least one second site, wherein the means is furthermore configured to irradiate the at least one first site with the at least one particle beam in order to set the electrostatic charge of the sample.
